(19) United States
(12) Patent Application Publication
(10) Pub. No.: US 2010/0301459 A1
(43) Pub. Date: Dec. 2, 2010

(54) METHOD FOR MANUFACTURING A SEMICONDUCTOR DEVICE AND A SEMICONDUCTOR DEVICE

(75) Inventors: Toshihiko Akiba, Tokyo (JP); Kenji Kozu, Tokyo (JP); Hisao Shigihara, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/782,798

(22) Filed: May 19, 2010

(30) Foreign Application Priority Data
May 26, 2009 (JP) 2009-125996

(51) Int. Cl. H01L 23/488; H01L 21/78; H01L 21/60

(52) U.S. Cl. 257/620; 438/462; 257/737; 257/E21.599; 257/E21.509; 257/E23.023

(57) ABSTRACT

The warpage of a semiconductor wafer or a semiconductor chip is inhibited. A method includes a step of successively forming, pads formed over the main surface of the semiconductor chip, an insulation layer formed by covering the main surface such that the pads are exposed, an insulation film formed over the insulation layer such that the pads are exposed, rewirings formed over the insulation film and electrically coupled with the pads, respectively, an insulation film formed over each rewirings such that portions of the rewirings are exposed, and bumps respectively bonded with the regions of the rewirings exposed from the insulation film. Any one of the insulation film and the insulation layer is formed such that a portion of an insulation layer or the insulation film formed closer to the back surface side than the insulation film or the insulation layer is exposed.

### CROSS-REFERENCE TO RELATED APPLICATIONS

The disclosure of Japanese Patent Application No. 2009-125996 filed on May 26, 2009 including the specification, drawings and abstract is incorporated herein by reference in its entirety.

### BACKGROUND OF THE INVENTION

The present invention relates to a semiconductor device and a manufacturing technology thereof. More particularly, it relates to a technology effectively applicable to a semiconductor device in which, over the pads-formed main surface of a semiconductor chip, wirings are formed, so that electrode terminals are formed at different positions from those of the pads.

There is a technology of flip-chip mounting a semiconductor chip over a wiring substrate as a semiconductor device package. For example, in Japanese Unexamined Patent Publication No. 2004-214501 (Patent Document 1), or in Japanese Unexamined Patent Publication No. 2005-93652 (Patent Document 2), there is disclosed a semiconductor device in which over the pads-formed main surface of a semiconductor chip, wirings are formed, so that electrode terminals are formed at different positions from those of the pads.

[Patent Document 1]

Japanese Unexamined Patent Publication No. 2004-214501

[Patent Document 2]

Japanese Unexamined Patent Publication No. 2005-93652

### SUMMARY OF THE INVENTION

In recent years, a semiconductor device has been regarded as being effective to which a redistribution wiring technology of distributing electrode pads formed on a semiconductor chip at other positions using wirings (redistribution wirings) as shown in Patent Document 1 or 2 so that one semiconductor chip is adaptable to various mounting forms. Such a semiconductor device is referred to as a WPP (Wafer Process Package) or a WL-CSP (Wafer Level Chip Scale Package).

However, there is also a demand for reduction in thickness of a semiconductor device. Thus, when the thickness of a semiconductor wafer to which a redistribution wiring technology has been applied is formed with a small thickness, warpage occurs in the semiconductor wafer. This has been revealed by the study of the present inventors.

The problem of warpage tends to occur when a grinding step to reduce the thickness of a semiconductor wafer is carried out after formation of an insulation film and wiring over the surface (main surface) of the semiconductor wafer in the case of the semiconductor device.

More particularly, in order to form wirings for changing the positions of electrode pads, a protective film (insulation film) is formed over the main surface of the semiconductor wafer. Further, the wirings are covered with a protective film. Accordingly, the overall thickness of the protective film formed over the main surface of the semiconductor wafer becomes larger than that of a semiconductor wafer to which the redistribution wiring technology is not applied. Herein, the following has been shown. The protective film is higher in linear expansion coefficient than a semiconductor wafer including silicon. For this reason, the shrinkage stress on the surface side of the semiconductor wafer also increases. Accordingly, the semiconductor wafer formed with a small thickness warps due to the shrinking action.

Occurrence of warpage in the semiconductor wafer results in a difficulty in: forming bump electrodes serving as external terminals; cleaning the semiconductor wafer; transporting the semiconductor wafer; or the like. For this reason, it is important to minimize the warpage of the semiconductor wafer.

Incidentally, as in Patent Document 1, with the technology of forming wirings over the surface of a semiconductor wafer using a copper-foiled adhesive sheet, the larger the amount of the copper foil added is, not only the more it becomes difficult to meet the trend toward a thinner semiconductor wafer, but also the more the manufacturing cost increases.

Whereas, as in Patent Document 2, with the technology in which the concave part is formed in the protective film, the protective film is in an integrally joined form. This makes it difficult to reduce the shrinkage stress occurring in the protective film.

In view of the foregoing problems, the present invention was completed. It is an object of the present invention to provide a technology capable of inhibiting warpage of a semiconductor wafer or a semiconductor chip.

The foregoing and other objects and novel features of the present invention will be apparent from the description of this specification and the accompanying drawings.

Summaries of the representative ones of the inventions disclosed in the present application will be described in brief as follows.

Namely, a method for manufacturing a semiconductor device in one embodiment of the present invention includes the steps of: (a) preparing a semiconductor wafer having a main surface, a plurality of device regions formed on the main surface, a plurality of first electrodes formed in each of the device regions, a scribe region formed between the adjacent device regions of the device regions, and a back surface arranged on the opposite side of the main surface; (b) grinding the back surface of the semiconductor wafer; (c) respectively disposing a plurality of conductive members to be respectively electrically coupled with the first electrodes on the main surface side; and (d) dividing the semiconductor wafer along the scribe region, and obtaining a plurality of semiconductor chips, wherein the main surface includes a semiconductor element layer including a plurality of semiconductor elements formed therein, and a plurality of first wirings stacked over the semiconductor element layer via a plurality of first insulation layers, and electrically coupled with the semiconductor elements; over the main surface, there are formed the first electrodes, a second wiring for electrically coupling the first electrodes and the semiconductor elements, and a second insulation layer formed covering the first and second wirings, and the first insulation layer in such a manner as to expose the first electrodes; the step (a) includes the steps of: (a1) forming a first insulation film over the second insulation layer in such a manner as to expose the first electrodes, (a2) forming a plurality of third wirings to be electrically coupled with the first electrodes, respectively, over the first insulation film, and (a3) forming a second insulation film over the third wirings in such a manner as to expose a portion of each of the third wirings; the conductive members are respectively bonded to the regions of the third wirings exposed through the second insulation film; and any one of the first insulation film and the second insulation film is formed in such a manner as to expose a portion of the insulation film or the insulation layer formed closer to the back surface side than the first insulation film or the second insulation film.

The effects obtainable by the representative ones of the inventions disclosed in the present application will be briefly described as follows.

Namely, the warpage of the semiconductor wafer can be inhibited.

### BRIEF DESCRIPTION OF THE DRAWINGS

FIG. 1 is a plan view showing the overall structure of a semiconductor device which is Embodiment 1 of the present invention;

FIG. 2 is a cross-sectional view along line A-A shown in FIG. 1;

FIG. 3 is an essential part enlarged plan view showing a part of each redistribution wiring shown in FIG. 1;

FIG. 4 is an essential part enlarged cross-sectional view along line B-B shown in FIG. 3;

FIG. 5 is an essential part enlarged cross-sectional view along line C-C shown in FIG. 3;

FIG. 6 is an essential part enlarged cross-sectional view along line D-D shown in FIG. 3;

FIG. 7 is an enlarged view of a part of each redistribution wiring shown in FIG. 1, and is an essential part enlarged plan view showing a different region from that in FIG. 3 on an enlarged scale;

FIG. 8 is an essential part enlarged cross-sectional view along line B-B shown in FIG. 7;

FIG. 9 is an essential part enlarged plan view showing a modified example of the periphery of the redistribution wiring shown in FIGS. 3 and 8;

FIG. 10 is a plan view showing the plane on the main surface side of a semiconductor wafer prepared in a wafer preparation step in a method for manufacturing a semiconductor device which is an embodiment of the present invention;

FIG. 11 is an essential part enlarged plan view of an E part shown in FIG. 10 on an enlarged scale;

FIG. 12 is an essential part enlarged cross-sectional view along line F-F shown in FIG. 11;

FIG. 13 is an essential part enlarged plan view showing a state in which an insulation film is formed in a prescribed shape over an insulation layer;

FIG. 14 is an essential part enlarged cross-sectional view along line F-F shown in FIG. 13;

FIG. 15 is an essential part enlarged plan view showing a state in which redistribution wirings are formed over the insulation film shown in FIG. 13;

FIG. 16 is an essential part enlarged cross-sectional view along line F-F shown in FIG. 15;

FIG. 17 is an essential part enlarged cross-sectional view showing a step of grinding the semiconductor wafer shown in FIG. 12;

FIG. 18 is an essential part enlarged cross-sectional view showing a step of disposing a bump serving as an external terminal over the semiconductor wafer with the back surface ground shown in FIG. 17;

FIG. 19 is a plan view showing the overall structure of a semiconductor device of Embodiment 2 of the present invention;

FIG. 20 is a cross-sectional view along line A-A shown in FIG. 19;

FIG. 21 is an essential part enlarged plan view showing a part of each redistribution wiring shown in FIG. 19;

FIG. 22 is an essential part enlarged cross-sectional view along line B-B shown in FIG. 21;

FIG. 23 is an essential part enlarged cross-sectional view along line C-C shown in FIG. 21;

FIG. 24 is an essential part enlarged cross-sectional view along line D-D shown in FIG. 21;

FIG. 25 is a plan view showing the overall structure of a semiconductor device which is a modified example of the semiconductor device shown in FIG. 19;

FIG. 26 is a cross-sectional view along line A-A shown in FIG. 25;

FIG. 27 is a plan view showing the overall structure of a semiconductor device which is a modified example of the semiconductor device shown in FIG. 1;

FIG. 28 is a cross-sectional view along line A-A shown in FIG. 27;

FIG. 29 is a plan view showing the overall structure of a semiconductor device which is a second modified example of the semiconductor device shown in FIG. 19;

FIG. 30 is a cross-sectional view along line A-A shown in FIG. 29;

FIG. 31 is a plan view showing the overall structure of a semiconductor device of Embodiment 5 of the present invention;

FIG. 32 is a cross-sectional view along line A-A shown in FIG. 31;

FIG. 33 is a plan view showing the overall structure of a semiconductor device of Embodiment 6 of the present invention;

FIG. 34 is a cross-sectional view along line A-A shown in FIG. 33;

FIG. 35 is a cross-sectional view showing the overall structure of a semiconductor device of Embodiment 7 of the present invention;

FIG. 36 is a cross-sectional view showing the overall structure of a semiconductor device of Embodiment 8 of the present invention;

FIG. 37 is an essential part enlarged cross-sectional view showing a modified example of each redistribution wiring shown in FIG. 34; and

FIG. 38 is an essential part enlarged cross-sectional view showing a modified example of bumps shown in FIG. 7.

### DETAILED DESCRIPTION OF THE PREFERRED EMBODIMENTS

### Explanation of Description Form, Basic Terms, and Methods in the Present Application

In the present application, in the following description of embodiments, the description may be divided into a plurality of sections, or the like for convenience, if required. However, unless otherwise specified, these are not independent of each other, but, are respective parts of a single example, in a relation such that one is a detailed explanation of a part of the other, a modification example of a part or the whole, or the like of the other, irrespective of the order of description. Further, in principle, the repetitive description of the same parts will be omitted. Whereas, respective constitutional elements in embodiments are not essential, unless otherwise specified, or except for the case where the number is theoretically limiting, and unless otherwise apparent from the context.

Similarly, in the description of embodiments, and the like, the term “X including A” or the like for the material, composition, or the like does not exclude the one including an element other than A as one of main constitutional elements unless otherwise specified and unless otherwise apparent from the context. For example, for the component, the term is used to embrace “X including A as a main component”, and the like. For example, it is naturally understood that the term “silicon member” or the like herein used is not limited to pure silicon but also embraces a SiGe (silicon germanium) alloy, other multinary alloys containing silicon as a main component, and other members containing additives, and the like. Whereas, gold plating, a Cu layer, nickel plating, or the like, herein used is assumed to embrace not only the pure one but also a member containing gold, Cu, nickel, or the like as a main component, unless otherwise specified.

Further, also when specific numerical values and quantities are mentioned, unless otherwise specified, except when they are theoretically limited to the numbers, and unless otherwise apparent from the context, each numerical value may be a numerical value of more than the specific numerical value, or may be a numerical value of less than the specific numerical value.

Below, embodiments of the present invention will be described in details by reference to the accompanying drawings.

### Embodiment 1

### Structure of Semiconductor Device

In this embodiment, a description will be given by taking a WPP type semiconductor device to which a redistribution wiring technology of distributing the positions of electrode pads formed over a semiconductor chip to other positions using wirings (redistribution wirings) has been applied (which will be hereinafter simply referred to as a WPP).

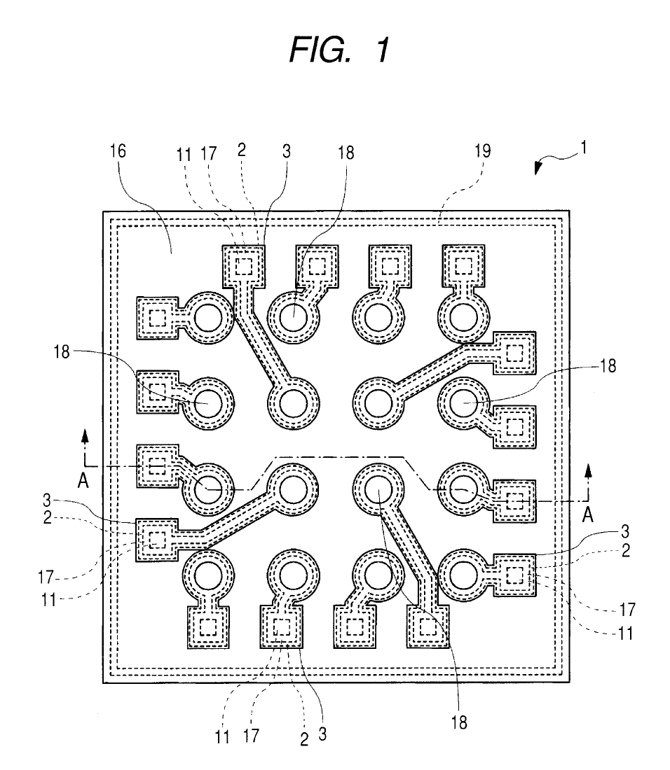

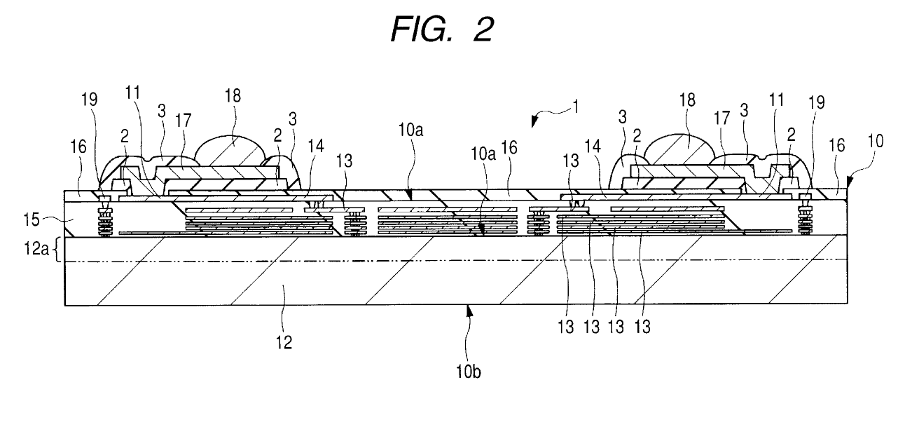

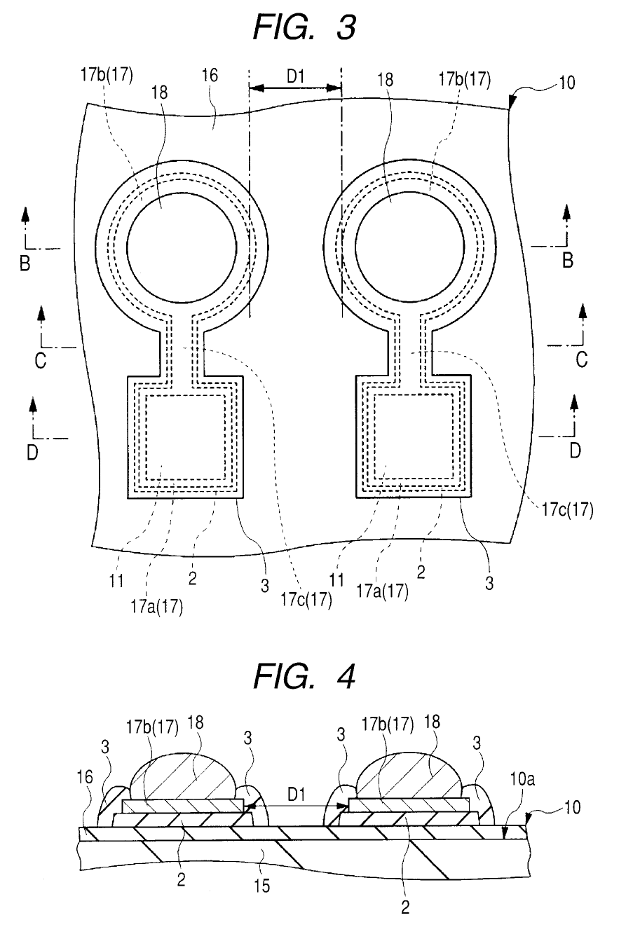

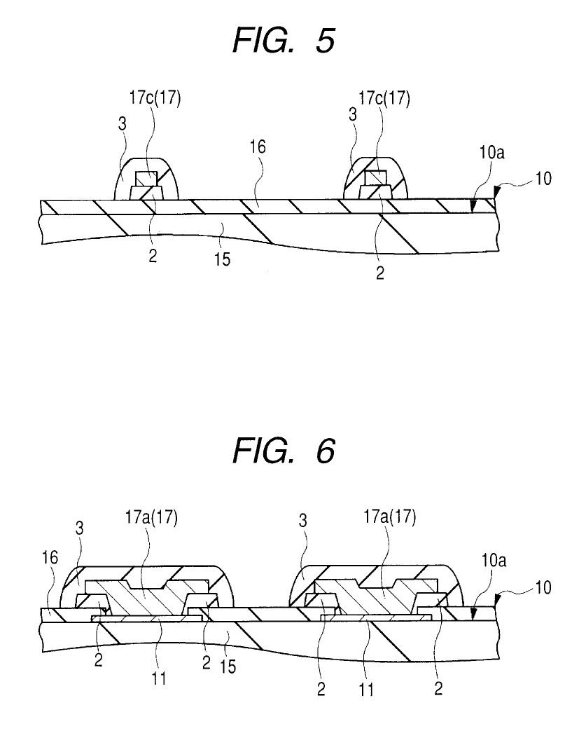

FIG. 1 is a plan view showing the overall structure of a semiconductor device of this embodiment; FIG. 2 is a cross-sectional view along line A-A shown in FIG. 1. Whereas, FIG. 3 is an essential part enlarged plan view showing a part of each redistribution wiring shown in FIG. 1; FIGS. 4, 5, and 6 are essential part enlarged cross-sectional views along line B-B, line C-C, and line D-D, respectively, shown in FIG. 3. Incidentally, in FIG. 1, for ease of view, the WPP is shown with reduced external terminals thereof. However, the trend toward so-called finer-pitch higher-pin-count, formation of more external terminals in a smaller area, has been pursued due to recent requirements for smaller size and higher function of semiconductor devices. The technology described in Embodiments below is also applicable to fine-pitch high-pin-count semiconductor devices.

A WPP 1 which is a semiconductor device of this embodiment has a semiconductor chip 10 having a main surface 10a, a plurality of pads (electrode pads) 11 formed over the main surface 10a, and a back surface 10b arranged on the opposite side of the main surface 10a.

The semiconductor chip 10 has a semiconductor substrate 12 which is a base material including, for example, silicon (Si). In the main surface 10a of the semiconductor substrate 12, a semiconductor element layer 12a is disposed. In the semiconductor element layer 12a, a plurality of semiconductor elements such as transistors and diodes are formed.

The plurality of semiconductor elements formed in the semiconductor element layer 12a are electrically coupled to the plurality of the pads 11, respectively, via a plurality of wirings (intra-chip wirings) 13 formed in the main surface 10a, and a surface wiring 14 formed over the main surface 10a. Incidentally, the pad 11 includes apart of the surface wiring 14.

The wirings 13 are embedded wirings including, for example, copper (Cu). The wirings 13 are formed with the so-called damascene process as follows. Namely, grooves or holes are formed in an insulation layer 15 formed on the main surface 10a side. In the grooves or the holes, a conductive metal material such as copper is embedded. Then, the surface is polished to form the wirings. The insulation layers 15 are inorganic insulation layers including a semiconductor compound such as silicon oxide (SiOC) or tetraethylorthosilicate (TEOS) from the viewpoint of improving the adhesion with the semiconductor substrate which is a base material. Further, the wirings 13 establish an electric coupling between the plurality of the semiconductor elements, or establishes an electric coupling of the plurality of the semiconductor elements with respective pads 11, thereby to form a circuit. However, in order to ensure the routing space of the wiring routes, the wirings 13 are stacked in a plurality of layers via the plurality of the insulation layers 15.

Incidentally, the main surface 10a of the semiconductor chip 10 denotes from the plural-semiconductor-elements formation surface to the pads 11 formation surface, i.e., to the top surface of the insulation layer 15 stacked at the uppermost stage of the insulation layers 15 stacked in multiple layers. Therefore, the semiconductor element layer 12a in which a plurality of semiconductor elements are formed, and the surface for forming therein the wirings 13 stacked over the semiconductor element layer 12a via the plurality of the insulation layers 15, and electrically coupled with the plurality of the semiconductor elements are included in the main surface 10a.

Over the main surface 10a, there are formed the pads 11, and the surface wirings 14 integrally formed with the pads 11 and establishing an electric coupling between the plurality of the pads 11 and the semiconductor elements via the wirings 13, respectively. The pads 11 and the surface wirings 14 include, for example, aluminum (Al), and are covered with the insulation layer 16 serving as a passivation film for protecting the main surface 10a. The insulation layer 16 is, as with the insulation layers 15, an inorganic insulation layer including a semiconductor compound such as silicon oxide (SiO) or silicon nitride (SiN) from the viewpoint of improving the adhesion with the insulation layer 15.

Whereas, in order to make each pad 11 serve as an external terminal of the semiconductor chip 10, in the surface of the pad 11 (the surface arranged on the opposite side of the opposing surface from the main surface 10a), an opening is formed in the insulation layer 16. Thus, the pad 11 is exposed through the insulation layer 16 at the opening.

Further, the main surface 10a is in the planar shape of a rectangle. The pads 11 are formed along respective sides forming the outer edge of the main surface 10a. In other words, the pads 11 are formed closer to the periphery of the main surface 10a. Thus, the pads 11 are disposed closer to the periphery of the main surface 10a. This is preferable in that the wire length can be reduced, for example, when the semiconductor chip 10 is mounted on a wiring board or a leadframe, and the wire bonding technology is applied thereto in which the pads 11 and the leads are electrically coupled with each other via wires. The WPP 1 of this embodiment can be electrically coupled with leads formed on a wiring board or the like via bumps described later. However, by arranging the pads 11 along respective sides forming the outer edge of the main surface 10a, it is possible to share a common manufacturing step between a semiconductor device to which the wire bonding technology is applied, and the semiconductor chip 10. As a result, it is possible to improve the manufacturing efficiency. The WPP 1 of this embodiment is preferable in this respect.

Herein, in the WPP 1 of this embodiment, redistribution wirings (wirings) 17 are formed over the pads 11, thereby to change the planar positions of the bumps (conductive members) 18 serving as external terminals to different positions from those of the pads 11. Such formation of the redistribution wirings 17 can provide positions corresponding to the positions of the terminals (bonding leads) formed on a wiring substrate (mounting substrate) on which the WPP 1 is mounted. This allows a direct coupling with the terminals of the mounting substrate via the bumps 18. For this reason, the mounting area in the mounting side of the mounting substrate can be reduced. Further, forming the redistribution wirings 17 over the main surface 10a of the semiconductor chip 10, it is possible to more reduce the mounting height as compared with the case where the semiconductor chip 10 is mounted on a mounting substrate via a wiring substrate called an interposer substrate.

The redistribution wiring 17 is configured, for example, as follows. Namely, over the insulation layer 16, an insulation film (organic insulation film) 2 including an organic compound such as a polyimide resin is formed. Over the insulation film 2, the redistribution wiring 17 including a conductive metal material obtained by stacking, for example, a nickel film on copper is formed in a prescribed pattern. Herein, the insulation film 2 is formed between the redistribution wiring 17 and the insulation layer 16. This is in order to prevent or inhibit the following: for example, a parasitic capacitance is formed between the redistribution wiring 17 and semiconductor elements or the wirings 13 formed in the main surface 10a of the semiconductor chip 10, and becomes a cause of deterioration of characteristics such as noise. Therefore, the insulation film 2 is preferably formed of a material having a low dielectric constant. Thus, in this embodiment, as the insulation film 2, there is used a polyimide resin film, a benzocyclobutene (BCB) film, a polybenzoxazole (PBO) film, or the like which is an organic insulation film having a lower dielectric constant than those of the insulation layers 15 and 16 which are inorganic insulation layers. Whereas, from the viewpoint of preventing or inhibiting the formation of the parasitic capacitance, a larger thickness of the insulation film 2 is more preferable. For example, in this embodiment, the thickness of the insulation film 2 is larger than the thickness of the insulation layer 16 disposed at the underlying layer.

Further, in order to establish an electric coupling between each redistribution wiring 17 and each pad 11, at least a part of the pad 11 is exposed through the insulation film 2. Further, over the redistribution wiring 17, an insulation film (organic insulation film) 3 including an organic compound such as a polyimide resin is formed. The insulation film 3 is formed as a protective film for protecting the redistribution wiring 17 from oxidation, corrosion, migration, short circuit, or breakage. Further, the insulation film 3 is preferably formed of a material having a low elasticity from the viewpoint of absorbing and releasing a stress (thermal stress) applied on the bumps 18 which are external terminals, and include, for example, a solder material (including a lead-free solder material) after mounting the completed semiconductor device on a mounting substrate (motherboard). Thus, in this embodiment, as the insulation film 3, there is used a polyimide rein film which is an organic insulation film having a lower elasticity than those of the insulation layers 15 and 16 which are inorganic insulation layers. Whereas, from the viewpoint of surely covering the redistribution wiring 17, the thickness of the insulation film 3 is preferably set large. For example, in this embodiment, the thickness of the insulation film 3 is larger than the thickness of the insulation layer 16 disposed at the underlying layer.

Whereas, for example, when, after mounting of the WPP 1, deformation of the mounting substrate or the like due to, for example, a thermal effect occurs, so that a stress is applied to the WPP 1, the stress tends to concentrate to the bumps 18. When an excessive stress is applied to the bumps 18, the joint parts between the bumps 18 and the redistribution wirings 17 may be broken. The organic insulation film such as a polyimide resin film is lower in elasticity than an inorganic insulation layer such as a silicon oxide layer. Therefore, in this embodiment, by using the low elasticity organic insulation film as the insulation film 2, it is possible to release the stress when the stress is applied to the bumps 18. Also from the viewpoint of releasing the stress, the insulation film 2 is preferably formed with a large thickness. Whereas, also for the insulation film 3, by similarly forming the insulation film 3 with a large thickness, it is possible to improve the function of releasing the stress applied on the redistribution wiring 17.

In a part of a region of the insulation film 3 overlapping the redistribution wiring 17, an opening is formed. The redistribution wiring 17 is exposed through the opening from the insulation film 3. To the region at which a part of the redistribution wiring 17 is exposed (land part), each bump (conductive member, bump electrode, or solder ball) 18 serving as the external terminal of the WPP 1 is bonded. The redistribution wiring 17 is bonded to the pad 11 at a portion thereof, and bonded to the bump 18 which is the external terminal at another portion. In other words, the redistribution wiring 17 functions as a lead-out wiring for changing the planar position of the external terminal of the WPP 1 to a different position from that of the pad 11. Incidentally, as shown in FIGS. 3 to 6, the redistribution wiring 17 includes a bonding part 17a to be bonded to the pad 11, a land part 17b to be bonded to the bump 18, and a lead-out wiring 17c extending from the bonding part 17a to the land part 17b. The bonding part 17a and the land part 17b are each formed with a larger width than that of the lead-out wiring 17c from the viewpoint of ensuring wide bonding areas with the pad 11 and the bump 18 to which these are bonded, respectively, and improving the bonding reliability.

Herein, the insulation film 2 disposed in a layer underlying the redistribution wiring 17 is formed, for example, as described above, from the viewpoint of preventing or inhibiting the following: a parasitic capacitance is formed between the redistribution wirings 17 and semiconductor elements or the wirings 13 formed in the main surface 10a of the semiconductor chip 10, and causes deterioration of characteristics such as noise. Whereas, the insulation film 3 formed in a layer overlying the redistribution wiring 17 is formed from the viewpoint of protecting the redistribution wiring 17 from oxidation, corrosion, migration, short circuit, or breakage.

From these viewpoints, it can also be considered as follows. The insulation films 2 and 3 are each formed in such a manner as to include openings formed only in regions in which the redistribution wirings 17 are bonded to the pads 11 and the bumps 18, and to cover entirely the insulation layer 16 or the insulation film 2 formed in the underlying layer (i.e., to cover the entire main surface 10a) at other regions thereof. However, a study by the present inventors has proved that, when the insulation films 2 and 3 are formed in such a manner as to cover the entire main surface 10a, the following problem occurs. Namely, there arises a problem that warpage occurs in the semiconductor chip 10.

More particularly, for the WPP 1 of this embodiment, on the main surface 10a side of the semiconductor chip 10, the multiple-layered insulation layers 15 and 16, and the insulation films 2 and 3 are stacked. On the other hand, on the back surface 10b side of the semiconductor chip 10, the insulation layer or the insulation film is not stacked, and the semiconductor substrate 12 which is a base material is exposed. When a different material from the base material is thus stacked on one side of the semiconductor chip 10, a shrinkage stress is applied to the semiconductor substrate 12 which is a base material due to a difference in linear expansion coefficient between the base material and the stacked members. Warpage occurs in the semiconductor substrate 12 due to the shrinkage stress.

The degree of warpage occurring in the semiconductor substrate 12 varies according to the intensity of the shrinkage stress applied to the semiconductor substrate 12 and the degree of the strength of the semiconductor substrate 12 thereagainst For example, for the WPP 1, from the viewpoint of reduction of the thickness, the back surface 10b side of the semiconductor chip 10 is ground, thereby to reduce the thickness of the semiconductor substrate 12. Thus, thinning of the WPP 1 is implemented. In this case, the strength of the semiconductor substrate 12 is reduced by thinning, and hence the degree of deformation, i.e., warpage increases.

Whereas, for the WPP 1, as the insulation film 2 or 3, an organic insulation film including a polyimide resin is used. The organic insulation film for use as the insulation film 2 or 3 is, as described above, lower in dielectric constant and elasticity than the inorganic insulation layer for use as the insulation layer 15 or 16. Therefore, the use of the organic insulation film is preferable from the foregoing viewpoints of inhibiting the degradation of the characteristics and protecting the redistribution wiring 17. However, the linear expansion coefficient of the insulation film 2 or 3 is higher than that of the semiconductor substrate 12 which is a base material, and is also higher than that of the insulation layer 15 or 16.

For this reason, the effect of the shrinkage stress applied from the insulation film 2 or 3 to the semiconductor chip 10 is particularly large when the insulation films 2 and 3 are organic insulation films. In other words, the degree of warpage increases. Further, in this embodiment, as described above, respective thicknesses of the insulation films 2 and 3 are set larger than the thickness of the insulation layer 16. This also causes an increase in shrinkage stress.

Thus, an increase in degree of warpage of the WPP 1 results in variations in height of the bumps 18 formed on the main surface 10a side of the semiconductor chip 10. This causes defective mounting for mounting the WPP 1, resulting in reduction of the reliability of the semiconductor device on which the WPP 1 is mounted. Further, when the degree of warpage is large, a stress is applied to a main circuit formation region (device region), which may result in variations in characteristics of the semiconductor device.

Under such circumstances, the present inventors conducted a study on the technology of reducing the parasitic capacitance, or reducing the warpage of the WPP 1 without impairing the protecting function of the redistribution wiring 17 based on the foregoing problems and causes. As a result, the WPP 1 was configured as follows. Namely, the insulation films 2 and 3 are subjected to a patterning processing, so that a part of the insulation layer 16 formed in a layer underlying the insulation films 2 and 3 is exposed. This results in reduction of the distribution amount of the organic insulation film formed over the semiconductor chip 10. As a result, it is possible to reduce the shrinkage stress occurring due to the insulation films 2 and 3. This can reduce the degree of warpage.

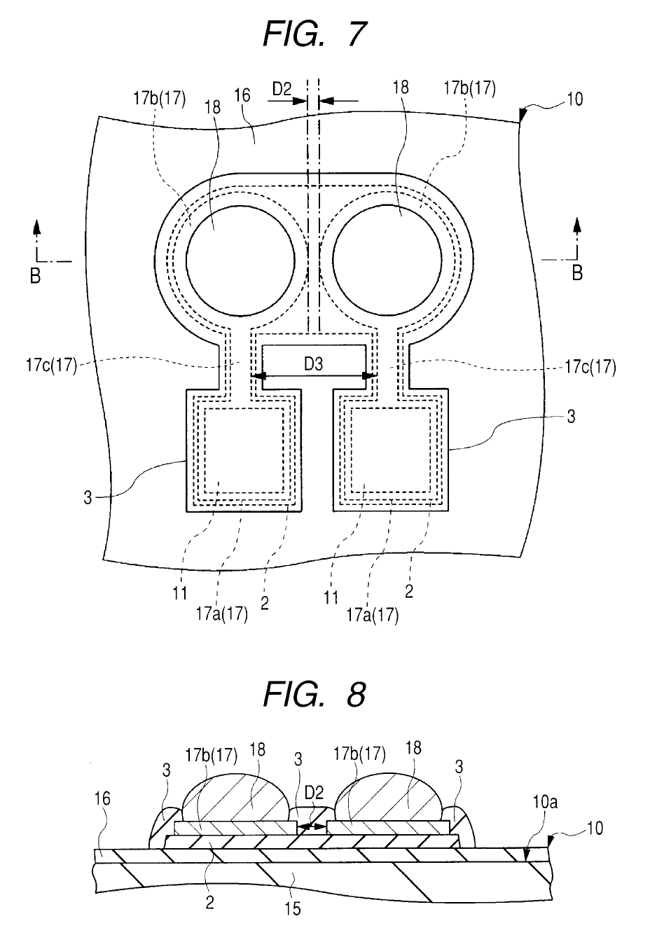

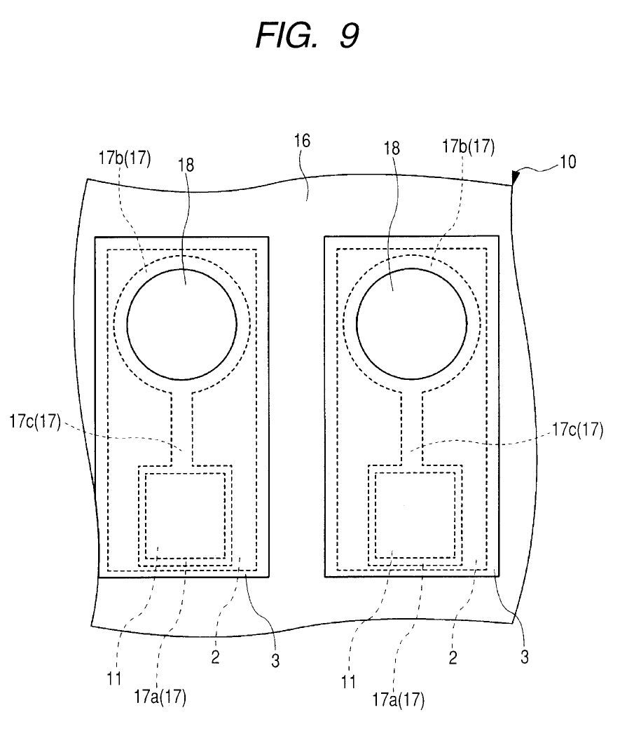

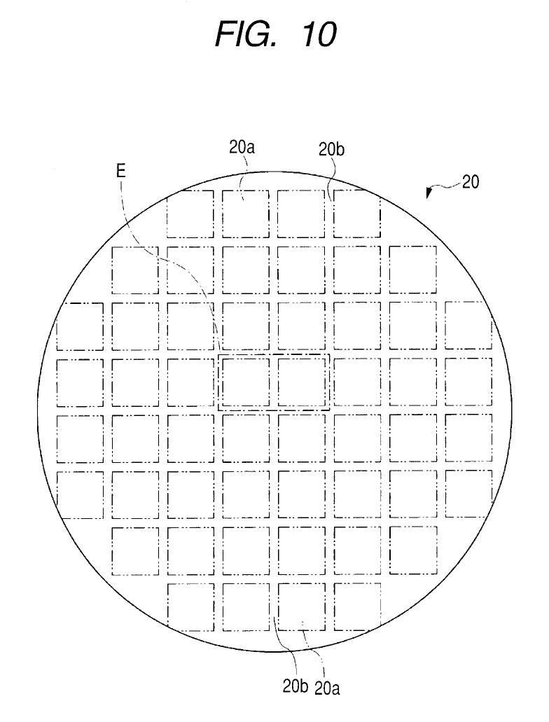

Below, the degree of exposure of the insulation layer 16 will be described in details from the viewpoint of the reduction of warpage. FIG. 7 is a view showing a part of each redistribution wiring shown in FIG. 1 on an enlarged scale, and an essential part enlarged plan view showing a different region from FIG. 3; and FIG. 8 is an essential part enlarged cross-sectional view along line B-B shown in FIG. 7. Further, FIG. 9 is an essential part enlarged plan view showing a modified example of the periphery of each redistribution wiring shown in FIGS. 3 and 8.

First, from the viewpoint of minimizing the distribution amount of the insulation films 2 and 3, as shown in FIG. 1, in particular preferably, for each redistribution wiring 17, the insulation film 2 disposed in a layer underlying the redistribution wiring 17 (see FIG. 2) and the insulation film 3 disposed in a layer overlying the redistribution wiring 17 are each independently formed. This can largely reduce the distribution amount of the insulation films 2 and 3 disposed over the semiconductor chip 10. Therefore, it is possible to particularly reduce the shrinkage stress applied to the semiconductor chip 10. Further, for each redistribution wiring 17, the insulation films 2 and 3 are formed. Accordingly, over the semiconductor chip 10, a plurality of the insulation films 2 and 3 are formed, so that respective insulation films 2 and 3 are formed apart from one another. In this case, even when a shrinkage stress occurs in respective insulation films 2 and 3, the stress can be dispersed by providing gaps between respective insulation films 2 and 3. This can reduce the effect of the stress applied to the semiconductor chip 10.

However, when the disposition pitch of the plurality of the redistribution wirings 17 is sufficiently large as shown in FIG. 3, the insulation films 2 and 3 can be formed for each redistribution wiring 17. However, when the disposition pitch is small as shown in FIG. 7, the adjacent insulation films 2 or insulation films 3 may be in contact with each other. In this case, when for each redistribution wiring 17, the insulation films 2 and 3 are attempted to be independently formed, there is a fear that each width of the insulation films 2 and 3 is reduced to almost as small as the width of the redistribution wiring 17. When the width of the insulation film 2 is set too small, the formability of the redistribution wiring 17 is degraded. Accordingly, there is a fear that the adjacent redistribution wirings 17 are short circuited according to the defective shape and the degree thereof of the redistribution wirings 17. Further, when the width of each insulation film 3 is set too short, a part (particularly, the side surface) of each redistribution wiring 17 is exposed. This may result in reduction of the function as the protective film. Thus, preferably, when the disposition pitch of the adjacent redistribution wirings 17 has a plurality of different regions over the semiconductor chip 10, in the wide disposition pitch region, the insulation films 2 and 3 are formed for each redistribution wiring 17, and in the narrow disposition pitch region, respective one insulation films 2 and 3 are formed for a plurality of the adjacent redistribution wirings 17. In other words, in the first region in which the adjacent redistribution wirings 17 are disposed at a first distance D1 (see FIG. 3) from each other, the insulation films 2 and 3 are each independently formed for each redistribution wiring 17, respectively. In the second region in which the redistribution wirings 17 are disposed at a second distance D2 smaller than the first distance D1 (see FIG. 7), preferably, respective one insulation films 2 and 3 are formed for a plurality of the adjacent redistribution wirings 17. As a result, each width of the insulation films 2 and 3 can be made larger than the width of the redistribution wiring 17 with reliability. This can prevent the defective shape of the redistribution wiring 17 and the degradation of the function of insulation film 3 as the protective film, described above.

Further, as shown in FIG. 7, there may be the following case: the distance between some portions of the redistribution wirings 17 is small, and the distance between other portions thereof is large. For example, in FIG. 7, there is shown a case where the distance between the land parts 17b is small, and the other distance between the lead-out wirings 17c or the bonding parts 17a is large. Other than this, a portion of the lead-out wiring 17c may be disposed locally at a small distance from the lead-out wiring 17c or the land part 17b of another redistribution wiring 17. In such a case, as shown in FIG. 7, in a region in which the distance D2 between the adjacent redistribution wirings 17 is small, one of, or both of the insulation film 2 disposed in a layer underlying each redistribution wiring and the insulation film 3 disposed in the overlying layer thereof are respectively formed integrally. In a region in which the distance D3 between the adjacent redistribution wirings 17 is larger than the distance D2, in particular preferably, the insulation films 2 and 3 are respectively formed apart from each other.

Incidentally, in FIGS. 1 to 8, as an embodiment in which the insulation films 2 and 3 are subjected to a patterning processing, thereby to expose portions of the insulation layer 16 formed in a layer underlying the insulation films 2 and 3, there is shown an embodiment in which the insulation films 2 and 3 are formed following the redistribution wirings 17 according to the shape and layout of the redistribution wirings. The embodiment in which portions of the insulation layer 16 are exposed also includes, in addition, the following embodiment: for example, the insulation films 2 and 3 covering entirely the top surface (the surface of the insulation layer 16 disposed on the main surface 10a side) of the semiconductor chip 10 are formed, and openings are formed in portions thereof, thereby to expose the insulation layer 16.

In this case, by forming the openings, it is possible to reduce the distribution amount of the insulation films 2 and 3 according to the area of the regions in which the insulation layer 16 has been exposed. This can more reduce warpage than the case where the entire insulation layer 16 is covered with the insulation films 2 and 3.

However, as described above, from the viewpoints of reduction of a noise, and protection of the redistribution wirings 17, the region requiring the formation of the insulation films 2 and 3 is limited to only the periphery of each redistribution wiring 17. Therefore, from the viewpoint of largely reducing the distribution amount of the insulation films 2 and 3, it is preferable that as shown in FIGS. 1 to 8, the insulation films 2 and 3 are formed following the redistribution wirings 17. Further, when the insulation films 2 and 3 are formed following the redistribution wirings 17, it results in that respective redistribution wirings 17 are adjacent to each other via the gaps through which portions of the insulation layer 16 are exposed. As a result, it is possible to reduce respective planar areas of the plurality of the insulation films 2 and 3, respectively, integrally formed. Accordingly, the shrinkage stress is dispersed, resulting in an increase in effect of reducing the warpage of the WPP 1.

Herein, the wording “the insulation films 2 and 3 are formed following the redistribution wirings 17” means that the insulation films 2 and 3 are selectively formed around the region in which each redistribution wiring 17 is formed according to the shape (planar shape) and layout of the redistribution wiring 17. For example, the insulation films 2 and 3 shown in FIGS. 3 and 7 are both formed following the redistribution wirings 17. Further, in FIGS. 3 and 7, the outer edges of the insulation films 2 and 3 are formed along the outline of the redistribution wiring 17 (bent along the outer edge of the redistribution wiring 17). Still further, the outer edges of the insulation films 2 and 3 are formed so that respective outer edges thereof are arranged on the outside of the outer edge of the redistribution wiring 17. This is for the following reason. The redistribution wiring 17 is formed by, for example, an etching process. However, the wiring pattern is processed finely, and hence misalignment may occur. Thus, the outer edge of the insulation film 2 is formed larger than the outer edge of the redistribution wiring 17. As a result, even if a problem of misalignment occurs, the insulation film can be disposed between the redistribution wiring 17 and the semiconductor wafer 20 with reliability. However, as shown in FIG. 9, the insulation films 2 and 3 may be each formed with a larger width than that of the redistribution wiring 17 for each redistribution wiring 17. The insulation films 2 and 3 shown in FIG. 9 are also selectively formed around a region in which each redistribution wiring 17 is formed according to the shape and layout of the redistribution wiring 17. In this respect, the insulation films 2 and 3 can also be said to be formed following the redistribution wiring 17. In this case, the planar shapes of the insulation films 2 and 3 can be simplified, which allows easy patterning of the insulation films 2 and 3. Further, in this case, the area of the portion of the insulation film 2 around the redistribution wiring 17 is large. As a result, it is possible to allow for a large margin of processing precision for patterning of the redistribution wiring 17. In other words, the processability of the redistribution wiring 17 is improved.

However, from the viewpoint of reduction of the distribution amount of the insulation films 2 and 3, as shown in FIG. 3 or 7, the formation of the outer edges of the insulation films 2 and 3 (in a curved form)along the outline of each redistribution wiring 17 is preferable because such formation can more reduce the distribution amount. Particularly, when the semiconductor chip 10 is a controller type chip in which a control circuit for controlling an external device is formed, or when the semiconductor chip 10 is a so-called microcomputer chip including a processing circuit formed therein, the number of external terminals increases. For this reason, the number of the redistribution wirings 17 also increases accordingly. This results in enhancement of effect of reducing the distribution amount due to the formation of the insulation films 2 and 3 along the outline of each redistribution wiring 17.

### (Method for Manufacturing a Semiconductor Device)

Then, a manufacturing method of the WPP 1 will be described.

The method for manufacturing a semiconductor device of this embodiment has a wafer preparation step of preparing a semiconductor wafer; a back surface grinding step of grinding the back surface of the semiconductor wafer; an external terminal formation step of forming external terminals to be electrically coupled with semiconductor elements on the main surface side of the semiconductor wafer; and a singulation step of singulating the semiconductor wafer on a per device region basis, and obtaining the WPP 1. This method will be described step by step below.

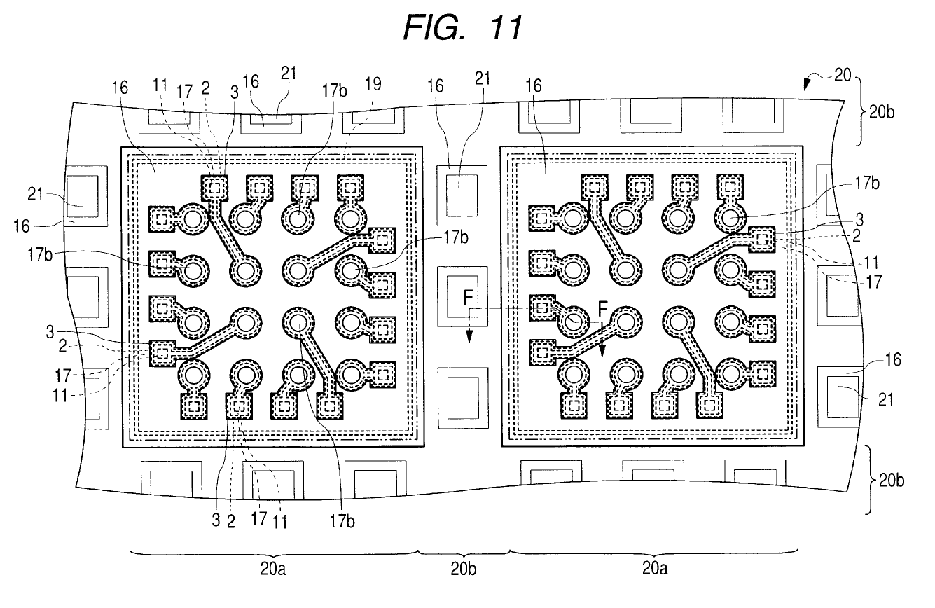

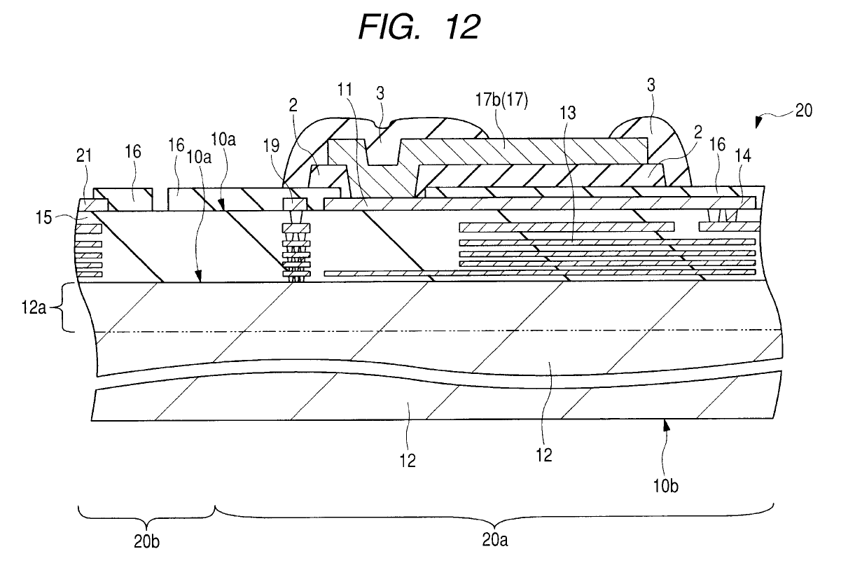

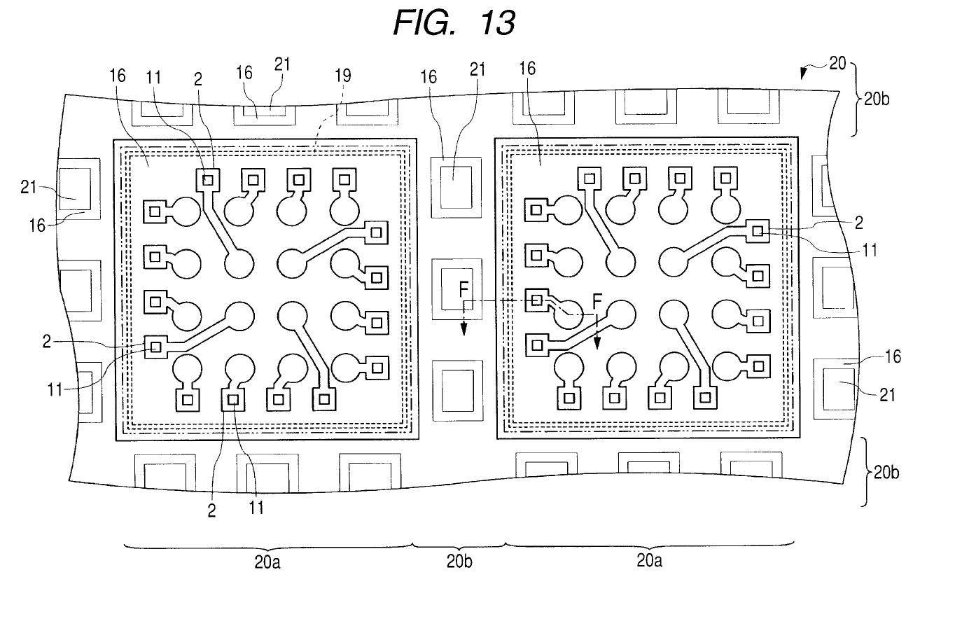

First, in the wafer preparation step, a wafer (semiconductor wafer) 20 shown in FIGS. 10 to 12 is prepared. FIG. 10 is a plan view showing a plane on the main surface side of the semiconductor wafer prepared in the wafer preparation step of this embodiment; FIG. 11 is an essential part enlarged plan view showing the E part shown in FIG. 10 on an enlarged scale; and FIG. 12 is an essential part enlarged cross-sectional view along line F-F shown in FIG. 11.

The wafer 20 prepared in this embodiment has a main surface 10a having a planar shape of generally a circle, and a back surface 10b arranged on the opposite side of the main surface 10a. Incidentally, the main surface 10a of the wafer 20 corresponds to the main surface 10a of the semiconductor chip 10 described by reference to FIGS. 1 to 9.

Further, the wafer 20 has a plurality of device regions 20a. Respective device regions 20a each correspond to the WPP 1 shown in FIGS. 1 and 2. Therefore, in a plurality of the device regions 20a, there are formed semiconductor elements, the wirings 13, the insulation layers 15, the pads 11, the surface wiring 14, and the insulation layer 16 included in the semiconductor chip 10 respectively described by reference to FIGS. 1 to 9. Further, over the insulation layer 16, the insulation films 2 and 3 and the redistribution wirings 17 are formed.

Further, a scribe region 20b is formed between the adjacent device regions 20a of the plurality of the device regions 20a. The scribe region 20b is formed in a lattice, and divides the top of the main surface 10a of the wafer 20 into a plurality of the device regions 20a. Whereas, in the scribe region 20b, there are formed a plurality of TEG's (Test Element Groups) 21, and the like, for confirming whether or not the semiconductor elements and the like formed in the device regions 20a are properly formed, respectively.

The wafer 20 shown in FIGS. 10 to 12 is formed in the following manner. First, the semiconductor substrate 12 which is a generally circular wafer (e.g., silicon wafer) serving as the base material is prepared. For each device region 20a shown in FIGS. 10 and 11, on the main surface 10a side, the semiconductor element layer 12a through the insulation layer 16 shown in FIGS. 1 and 2 are formed. Namely, each member corresponding to the semiconductor chip 10 is formed. Incidentally, in this step, the semiconductor substrate 12 serving as the base material is in the shape of generally a circle. However, the semiconductor substrate 12 is finally singulated, to be in the planar shape of a rectangle. The insulation layer 16 includes openings formed in regions overlapping the pads 11, so that the surfaces of the pads 11 are exposed through the openings, respectively.

Incidentally, between the pads 11 and the outer edge portion of the device region 20a, a so-called guard ring 19 for protecting the inside region of the device region 20a is disposed. The guard ring 19 is disposed in such a manner as to surround the periphery of the region in which the pads 11 are disposed along respective sides of the outer edge of the device region 20a forming a rectangle.

The method for forming each member included in the semiconductor chip 10 has no particular restriction. For example, there can be used a known method in which an integrated circuit is formed in a semiconductor wafer, and over the main surface thereof, electrode pads are formed. Therefore, a detailed description thereon will be omitted.

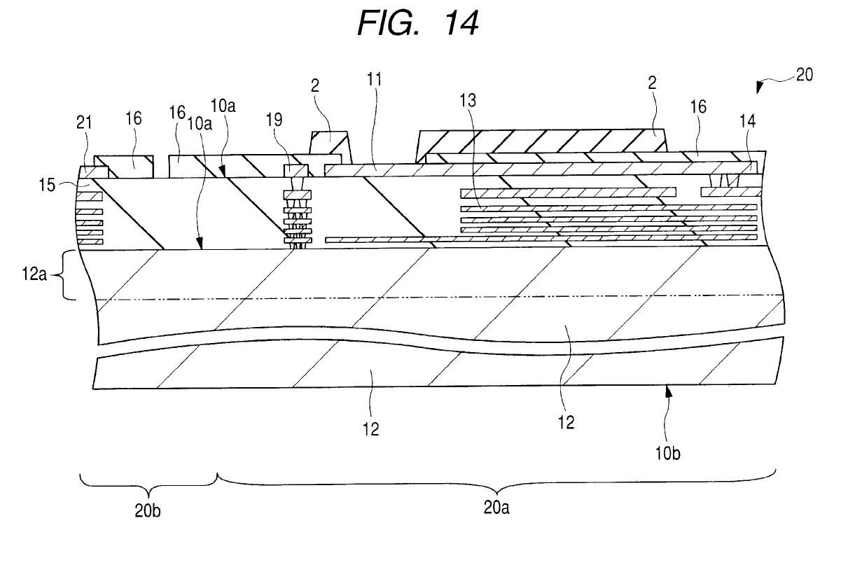

Then, on the top surface side of the insulation layer 16, the insulation film 2 is formed in such a manner as to expose the pads 11. FIG. 13 is an essential part enlarged plan view showing a state in which an insulation film is formed in a prescribed shape over the insulation layer; and FIG. 14 is an essential part enlarged cross-sectional view along line F-F shown in FIG. 13.

In this step, the insulation film 2 is formed so that portions of the insulation layer 16 are exposed through the insulation film 2. Therefore, the following method can be used. For example, the insulation film 2 covering entirely the insulation layer 16 is formed. Then, regions of the insulation film 2 except for the regions to be left as the insulation film 2 are removed by etching. Thus, patterning of the insulation film 2 is carried out, thereby to expose the insulation layer 16. In this case, patterning can be carried out in one step together with patterning for formation of openings when openings are formed in the regions overlapping the pads. Therefore, it is possible to prevent addition of another manufacturing step due to patterning of the insulation film 2.

In this step, preferably, the insulation film 2 is formed in only each device region 20a, and the insulation film 2 is not formed in the scribe region 20b. This is for the following reason. When the insulation film 2 is also formed in the scribe region 20b, the area of the integrally formed insulation film 2 increases. This results in a larger effect of the shrinkage stress occurring in the insulation film 2. Particularly, at the stage of the wafer 20 before singulation, formation of the insulation film 2 entirely over the top surface of the wafer 20 results in a very large shrinkage stress particularly in the periphery. This causes large warpage of the wafer 20 during the manufacturing step.

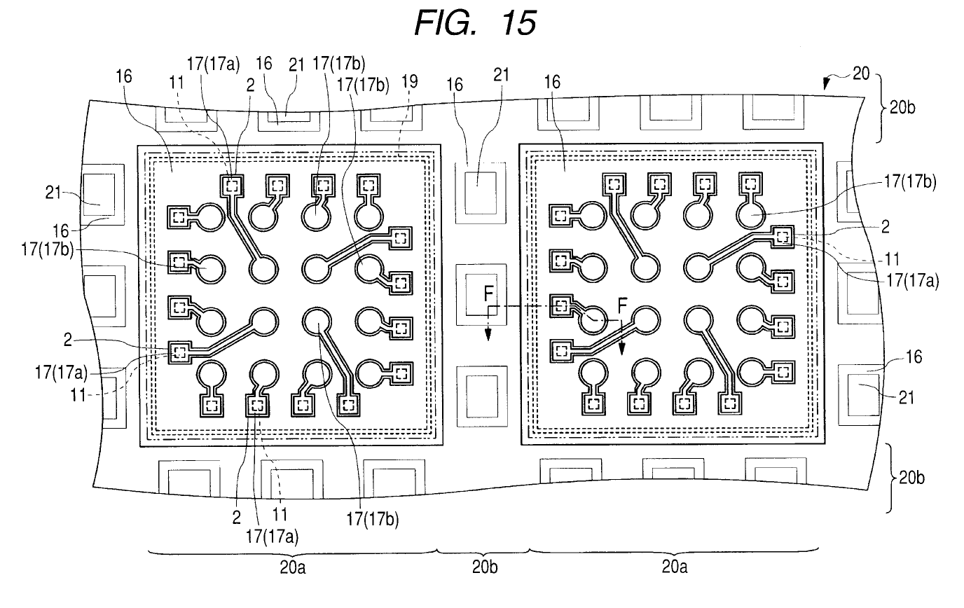

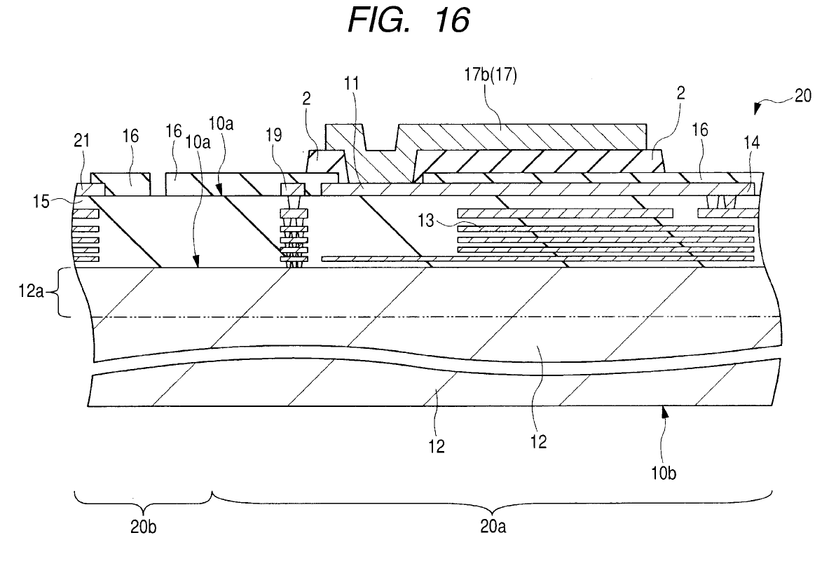

Then, on the top surface side of the patterned insulation film 2, the redistribution wiring 17 is formed. FIG. 15 is an essential part enlarged plan view showing a state in which redistribution wirings are formed over the insulation film shown in FIG. 13; and FIG. 16 is an essential part enlarged cross-sectional view along line F-F shown in FIG. 15.

In this step, over the insulation film 2, the redistribution wiring 17 including, for example, copper (Cu) is formed. The redistribution wiring 17 can be formed in the following manner. For example, with a sputtering process, a seed layer is formed. The seed layer is patterned using a photoresist film, and then, is formed in a prescribed pattern with an electrolytic plating process. The redistribution wiring 17 is formed in such a manner as to be bonded with, and to be electrically coupled with each pad 11 at a portion thereof, and to extend toward a different position from that of the pad 11 at another portion thereof. As a result, the position of each external terminal of the WPP 1 (see FIG. 1) can be changed to a different position from that of the pad 11.

Then, as shown in FIGS. 11 and 12, over the insulation film 2 and the redistribution wiring 17, the insulation film 3 is formed, thereby to cover the redistribution wiring 17. In this step, the insulation film 3 is formed over the redistribution wiring 17 in such a manner as to expose a portion (a portion serving as the land part 17b) of the redistribution wiring 17.

Further, in this step, the insulation film 3 is formed in such a manner as to expose the insulation layer 16. However, it is preferable that the side surface of the insulation film 2 is covered with the insulation film 3. Covering of the side surface of the insulation film 2 with the insulation film 3 results in that the surface of the insulation film 2 in contact with the redistribution wiring 17 (i.e., the top surface of the insulation film 2) is covered with the insulation film 3. In this embodiment, the insulation films 2 and 3 are not formed in such a manner as to cover the entire top surface of the insulation layer 16. Therefore, it is necessary to effectively prevent the occurrence of corrosion or the like in the redistribution wiring 17 due to the moisture in the atmosphere and the like. From the viewpoint of preventing or inhibiting the penetration of moisture, it is preferable that the path from the region exposed in the atmosphere to the redistribution wiring 17, i.e., the path which can be the penetration path of moisture is elongated. Further, by providing a bent part in the path, it is possible to complicate the path. This can inhibit penetration of moisture and the like. In this embodiment, by covering the side surface of the insulation film 2 with the insulation film 3, it is possible to complicate the path for the moisture in the atmosphere to penetrate into the redistribution wiring 17. Further, it is possible to elongate the penetration path length. Therefore, such a configuration is preferable from the viewpoint of inhibiting the corrosion and the like of the redistribution wiring 17, and improving the reliability.

As the formation method of the insulation film 3, the following method can be employed. As with the insulation film 2, for example, the insulation film 3 covering entirely the insulation layer 16 is formed. Then, other regions than regions to be left as the insulation film 3 are removed by etching, thereby to pattern the insulation film 3. Thus, the insulation layer 16 is exposed. In this case, when openings are formed as the land parts 17b, patterning can be carried out in one step together with patterning for formation of the openings. Therefore, it is possible to prevent addition of another manufacturing step due to patterning of the insulation film 3.

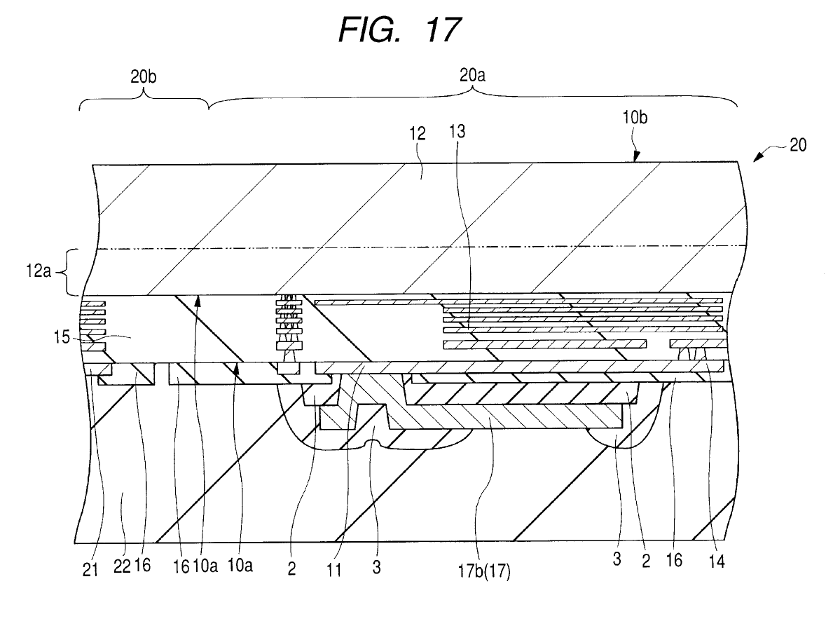

Then, in the back surface grinding step, the back surface 10b of the semiconductor wafer 20 is ground. FIG. 17 is an essential part enlarged cross-sectional view showing the step of grinding the semiconductor wafer shown in FIG. 12. In this step, by grinding the back surface 10b arranged on the opposite side of the main surface 10a in which semiconductor elements have been formed, the thickness of the semiconductor wafer 20 is reduced.

For the WPP 1 shown in FIG. 1 or FIG. 2, each redistribution wiring 17 is formed directly on the main surface 10a of the semiconductor chip 10. Therefore, as compared with the case of mounting on the mounting substrate via an interposer substrate, the thickness required for the wiring layer to form the redistribution wiring 17 therein can be more reduced. Further, by proving the step of grinding the back surface 10b of the semiconductor wafer 20 as in this embodiment, it is possible to further reduce the thickness of the resulting WPP 1.

As the method for reducing the thickness of the WPP 1, there can also be considered a method in which the thickness of the wafer serving as the base material (in this embodiment, a silicon wafer) is previously reduced. However, in this case, when the thickness is extremely reduced, in respective steps of forming semiconductor elements and the like in a wafer serving as the base material, the handling property is degraded, which causes breakage of the wafer. Thus, in this embodiment, on the main surface 10a side of the wafer, processing is performed on the wafer having a first thickness enough to allow prevention of reduction of the handling property in respective steps of forming semiconductor elements, the wirings 13, the insulation layers 15 and 16, the insulation films 2 and 3, and the redistribution wiring layer 17. Then, the back surface 10b side is ground, resulting in a second thickness smaller than the first thickness. As a result, it is possible to reduce the thickness of the resulting WPP 1 while preventing breakage of the wafer during the manufacturing step.

Further, when the thickness of the wafer 20 is reduced with the entire top surface side of the insulation layer 16 covered with the insulation films 2 and 3, warpage becomes more likely to occur in the wafer 20 according to the relation between the shrinkage stress resulting from the insulation films 2 and 3 and the rigidity of the base material including silicon. Therefore, from the viewpoint of reducing the effect of the shrinkage stress resulting from the insulation films 2 and 3 before the step of reducing the thickness of the wafer 20, the step of patterning the formed insulation films 2 and 3, and exposing portions of the insulation film formed closer to the back surface side of the wafer 20 than the insulation film 2 or the insulation film 3, or portions of the insulation layer 16 is preferably carried out before this step of grinding the back surface 10b of the wafer 20.

The grinding means in this step has no particular restriction. However, the back surface 10b of the wafer 20 can be ground by using a grinding member such as grindstone. Further, in order to prevent residue or the like upon grinding from remaining on the back surface 10b of the wafer 20, it is preferable to perform a polishing processing on the back surface 10b using, for example, polishing particles. In this step, polishing is preferably performed with a protective tape (protective sheet) 22 covering the main surface 10a side of the wafer 20, i.e., the surface including the insulation films 2 and 3 formed thereon, attached thereon. This is in order to protect the main surface 10a side from breakage due to application with an external force or the like during grinding. Further, for the protective tape 22, there is preferably used a material capable of being selectively reduced in adhesive strength by being externally applied with energy, such as an ultraviolet curable resin. In this embodiment, as described above, the insulation films 2 and 3 are respectively formed apart from each other. Accordingly, when an external force is applied in the out-of-plane direction of the main surface 10a (the direction of thickness of the wafer 20), peeling may occur. Therefore, by using a material capable of being selectively reduced in adhesive strength by being externally applied with energy as the protective tape 22, the protective tape 22 can be peeled after reducing the adhesive strength of the protective tape 22. This can prevent peeling of the insulation films 2 and 3.

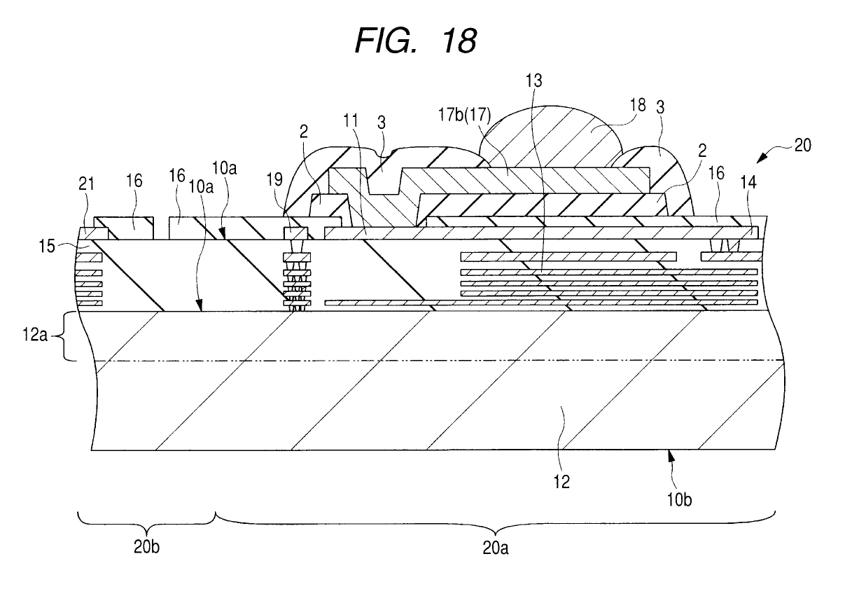

Then, in the external terminal formation step, the bumps 18 to be electrically coupled with a plurality of the pads 11 are disposed on the main surface 10a side. FIG. 18 is an essential part enlarged cross-sectional view showing a step of disposing bumps serving as external terminals on the semiconductor wafer with the back surface ground shown in FIG. 17.

In this embodiment, as the bumps 18, a conductive member including solder, and formed in the shape of generally a circle, a so-called solder ball is used. The formation method of the bumps 18 is, for example, as follows.

First, by a printing or transfer process, flux is supplied to the land part 17b including a portion of the redistribution wiring 17. A plurality of solder balls are aligned thereon using an alignment jig, and respectively mounted on the to-be-bonded sites of the redistribution wiring 17 (in this embodiment, the opening of the insulation film 3 through which the land part 17b is exposed). Then, by the reflow step of heating the wafer 20, respective solder balls are molten, and are bonded with the land part 17b, followed by heat radiation, resulting in the bump 18 shown in FIG. 18.

Herein, in this step, the wafer 20 is heated, and radiates heat. Accordingly, respective material including the insulation films 2 and 3 formed in the wafer 20 also thermally expand, and then shrink. For this reason, in this step, warpage tends to occur in the wafer 20 due to the difference in linear expansion coefficient between the organic insulation films such as the insulation films 2 and 3, and the insulation layers 15 and 16 which are inorganic insulation layers, the silicon wafer serving as the base material, or the like. Particularly, when the back surface 10b of the wafer 20 is ground, and is reduced in thickness, and then, heating and heat radiation are performed as in this embodiment, warpage tends to occur in the wafer 20 due to a shrinkage stress. Therefore, preferably, before performing this step, the insulation films 2 and 3 are previously patterned, so that portions of the insulation layer 16 arranged in the underlying layer are exposed.

Incidentally, from the viewpoint of preventing the warpage of the wafer 20, it is also conceivable that after performing this step requiring a heating process, the back surface grinding step is performed. This is because an increase in thickness of the wafer 20 can inhibit the occurrence of warpage even when a shrinkage stress occurs.

However, when the back surface grinding step is performed after the formation of the bumps 18, the flatness of the surface on the opposite side of the back surface 10b which is the grinding surface (i.e., the surface including the bumps 18 disposed thereon) remarkably decreases according to the size of each bump 18. This results in that the external force applied during grinding is intensively applied to the bumps 18 and portions of the back surface 10b (e.g., positions overlapping in plan view the device region). This may cause poor junction between the bump 18 and the redistribution wiring 17, or a malfunction of the semiconductor device. Therefore, from the viewpoint of preventing a stress from being excessively applied to the joint part between the bump 18 and the redistribution wiring 17, it is preferable that this step is performed after the back surface grinding step. Accordingly, in this embodiment, after reducing the thickness of the wafer 20, the wafer 20 is heated. Therefore, particularly, a countermeasure against the warpage of the wafer 20 becomes necessary as compared with a semiconductor device not subjected to the back surface grinding step. From this viewpoint, in this embodiment, the following process is particularly preferable in terms of allowing effective prevention or inhibition of the warpage of the wafer 20. Namely, before this step, the insulation films 2 and 3 are previously patterned, so that portions of the insulation layer 16 arranged in the underlying layer are exposed.

Then, in the singulation step, the wafer 20 is divided along the scribe region 20b, and is singulated on a per device region 20a basis. This results in a plurality of semiconductor chips 10 including, the insulation films 2 and 3, the redistribution wirings 17, and the bumps 18, formed on the main surface 10a side, i.e., the WPP 1 shown in FIGS. 1 and 2.

In this embodiment, in the scribe region 20b, basically, the insulation films 2 and 3 and the redistribution wiring 17 are not formed. Therefore, it is possible to apply a general dicing technology of dividing the semiconductor wafer, and obtaining a plurality of semiconductor chips thereto. For example, in this embodiment, by using a cutting jig called a dicing blade, the scribe region 20b is cut to be singulated into a plurality of WPP's 1.

### Embodiment 2

In Embodiment 1, a description was given to the structure in which the insulation film 2 and the insulation film 3 formed on the main surface side of the semiconductor chip 10 are respectively patterned, thereby to expose the insulation layer 16 through both of the insulation film 2 and the insulation film 3. In this embodiment, a description will be given to a structure in which only any one of the insulation film 2 or the insulation film 3 is patterned.

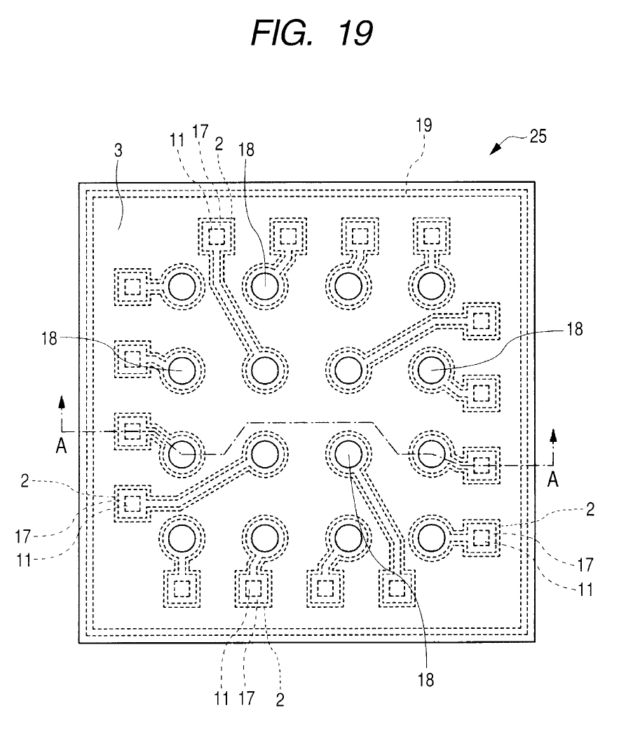

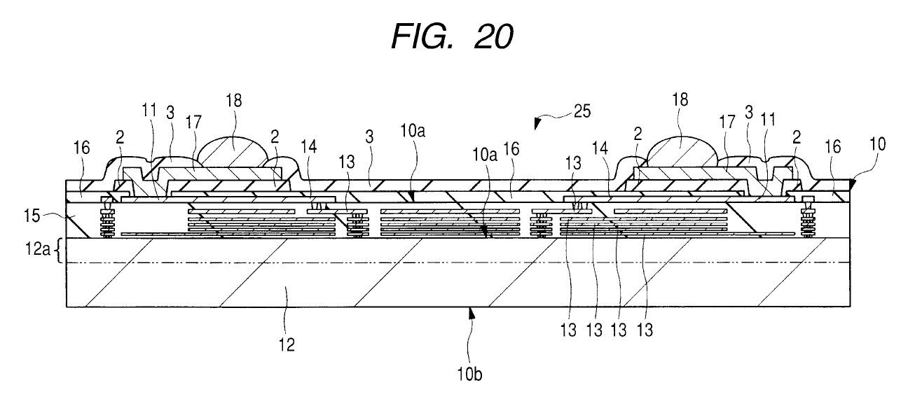

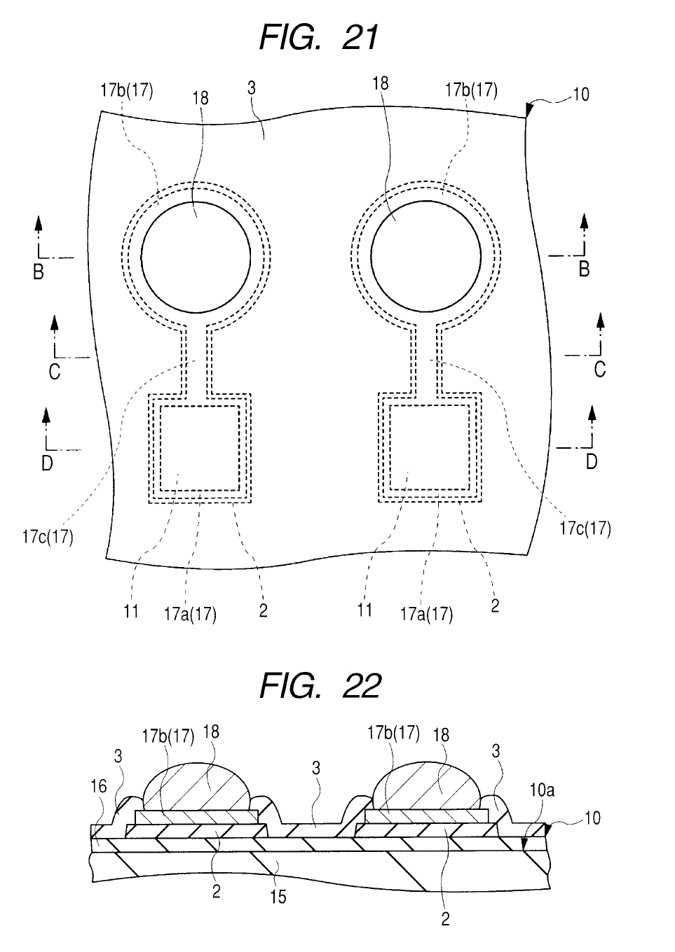

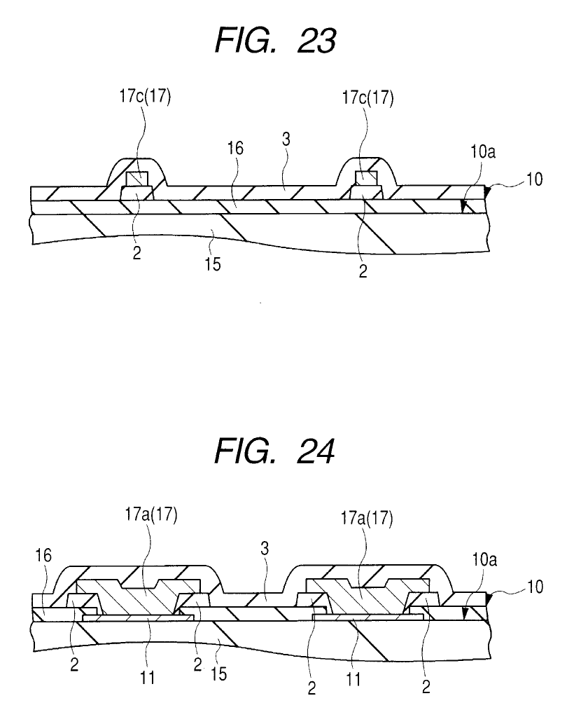

FIG. 19 is a plan view showing the entire structure of a semiconductor device of this embodiment; and FIG. 20 is a cross-sectional view along line A-A shown in FIG. 19. Whereas, FIG. 21 is an essential part enlarged plan view showing a portion of each redistribution wiring shown in FIG. 19; and FIGS. 22, 23, and 24 are essential part enlarged cross-sectional views along lines B-B, C-C, and D-D shown in FIG. 21, respectively.

The difference between the WPP 1 shown in FIGS. 1 and 2 described in Embodiment 1 and a WPP 25 of Embodiment 2 shown in FIGS. 19 to 24 resides in the planar shape of the insulation film 3. Namely, in this embodiment, the insulation film 3 is formed in such a manner as to cover the main surface 10a side of the semiconductor chip 10. The insulation layer 16 is partially exposed through the insulation film 2, but the exposed portions are also covered with the insulation film 3.

As described in Embodiment 1, from the viewpoint of preventing the warpage due to the shrinkage stress of the organic insulation film disposed over the main surface 10a of the semiconductor chip 10, the WPP 1 described in Embodiment 1 is more preferable. This is for the following reason. The insulation film 2 and the insulation film 3 which are organic insulation films are respectively patterned. This results in that a plurality of the organic insulation films are formed apart from one another. This can disperse the shrinkage stress.

However, for the WPP 25 shown in FIGS. 19 to 24, the insulation film 2 is patterned as with the insulation film 2 included in the WPP 1 described in Embodiment 1. In other words, in a layer underlying the insulation film 3, a plurality of the insulation films are formed apart from one another. For this reason, even when a shrinkage stress occurs in the insulation film 2 and the insulation film 3, respectively, during manufacturing of, or after completion of the WPP 25, the stress distributions thereof are different from each other. More specifically, the insulation film 3 is integrally formed over the main surface 10a of the semiconductor chip 10. Therefore, the shrinkage stress is transferred within the insulation film 3, and becomes strongest at the end thereof, in other words, at the periphery of the top surface of the WPP 25. However, for the shrinkage stress occurring in the insulation film 2, the shrinkage stress less transfers between a plurality of the adjacent insulation films 2, and the shrinkage stress is dispersed in the top surface of the WPP 25. For this reason, as compared with the case where the insulation film 2 is not patterned, it is possible to more reduce the warpage due to the shrinkage stress occurring in the insulation films 2.

Incidentally, as one embodiment in which the WPP 1 or the WPP 25 is mounted on a wiring substrate, mounting may be carried out by so-called face-down mounting as follows: with the surface including a plurality of the bumps 18 formed thereon, and the surface including the lands of the wiring substrate (the external terminals on the wiring substrate side, disposed at positions respectively opposing the bumps 18) formed thereon, opposing each other, the bumps 18 and the lands are electrically coupled with each other, respectively. In this case, from the viewpoint of preventing the poor electric coupling due to breakage of the bumps 18, peeling of the joint part, or the like caused by concentration of the stress to each bump 18, the space between the bumps 18 formation surface and the lands formation surface of the wiring substrate is preferably filled with an underfill resin including an organic resin material such as an epoxy type resin (in addition, an inorganic filler material may be added).

It is preferable that the underfill resin is firmly bonded to both of the bumps 18 formation surface and the lands formation surface of the wiring substrate in order to reduce the stress applied to the bumps 18. Herein, in the WPP 25 of this embodiment, the insulation layer 16 including an inorganic insulation material is covered with the insulation film 3 including an organic insulation material. Therefore, the adhesion with the underfill resin including an organic insulation material can be more improved for the WPP 25 than for the WPP 1 described in Embodiment 1. In other words, from the viewpoint of improving the adhesion with the underfill resin, the WPP 25 of Embodiment 2 is more preferable.

Further, in Embodiment 1, the following was described: from the viewpoint of effectively preventing the occurrence of corrosion or the like in the redistribution wirings 17 due to the moisture and the like in the atmosphere, it is preferable that the side surface of the insulation film 2 is covered with the insulation film 3. From this viewpoint, for the WPP 25 of this embodiment, it results in that the gaps between the spaced insulation films 2 are covered with the insulation film 3. Accordingly, the penetration path for moisture can be much reduced as compared with the WPP 1. Therefore, the WPP 25 is preferable from the viewpoint of inhibiting the corrosion and the like of the redistribution wirings 17, and improving the reliability.

### Modified Example

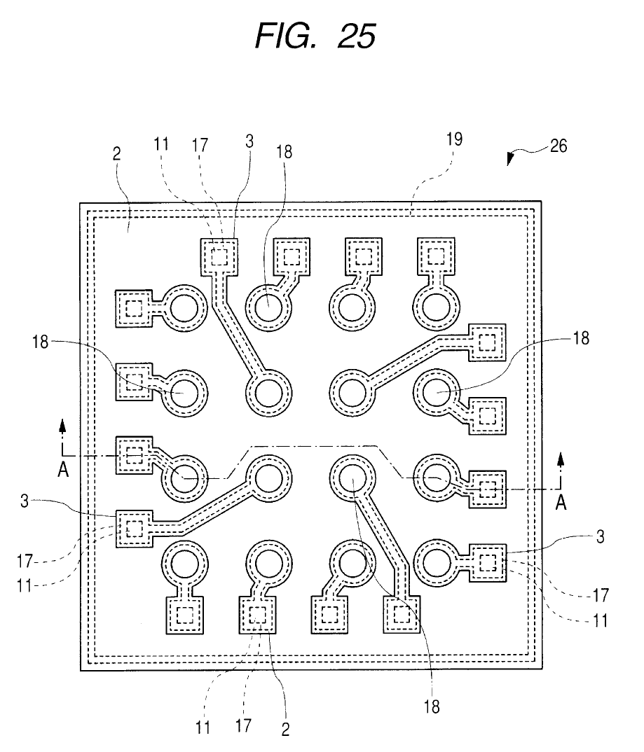

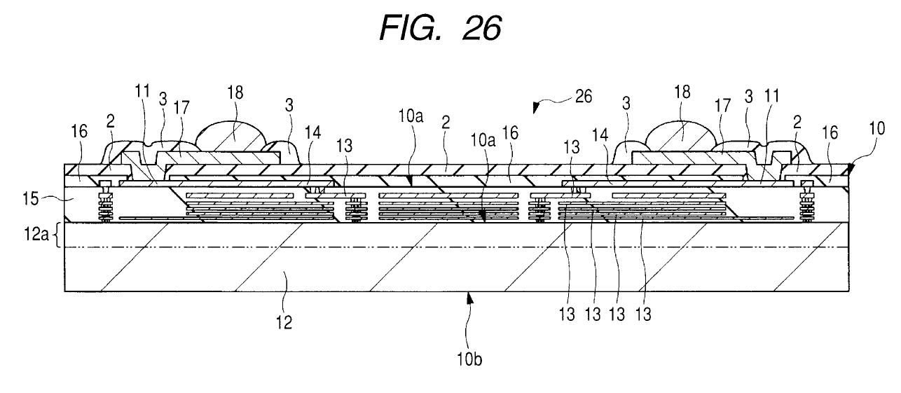

In FIGS. 19 to 24, a description was given to the case where the insulation film 2 is patterned. However, as a modified example thereof, it is also acceptable that the insulation film 3 is patterned. FIG. 25 is a plan view showing the overall structure of a semiconductor device which is a modified example of the semiconductor device shown in FIG. 19. FIG. 26 is a cross-sectional view along line A-A shown in FIG. 25.

The difference between the WPP 1 shown in FIGS. 1 and 2 described in Embodiment 1 and a WPP 26 shown in FIGS. 25 and 26 resides in the planar shape of the insulation film 2. Namely, in this embodiment, the insulation film 2 is formed in such a manner as to cover the insulation layer 16 disposed on the main surface 10a side of the semiconductor chip 10. The insulation film 3 is patterned in the same manner as with the WPP 1 described in Embodiment 1, so that portions of the insulation film 2 are exposed through the insulation film 3.

In the WPP 26, over the main surface 10a of the semiconductor chip 10, a plurality of the insulation films 3 are formed apart from one another. This can reduce the effect of the warpage due to the shrinkage stress occurring in each insulation film 3.

However, from the viewpoint of inhibiting the warpage of the semiconductor chip 10, the WPP 25 is more preferable than the WPP 26. This is because the effect of the shrinkage stress exerted on the warpage of the semiconductor chip 10 is larger for the insulation film 2 disposed on the lower layer side which is closer to the semiconductor chip 10. Further, from the viewpoint of effectively preventing occurrence of corrosion or the like in the redistribution wiring 17 due to moisture in the atmosphere, or the like, described in Embodiment 1, the WPP 25 and the WPP 1 described in Embodiment 1 are more preferable than the WPP 26. This is for the following reason. For the WPP 26, at the surface on which the redistribution wiring 17 is formed (the top surface of the insulation film 2), the lower end of the side surface of the insulation film 3 is arranged. This results in a simplified penetration path for moisture and the like. Therefore, as compared with the WPP 25 or the WPP 1, moisture and the like become more likely to penetrate therethrough.

Incidentally, in Embodiment 2, regarding a preferred embodiment of the planar shape of the insulation film 2 or the insulation film 3 to be patterned, and the effects thereof, a description overlapping that in Embodiment 1 was omitted. However, it is naturally understood that, as a modified example, other than the planar shape shown in FIGS. 21 to 24, the planar shape corresponding to FIGS. 7 to 9 described in Embodiment 1 is applicable.

### Embodiment 3

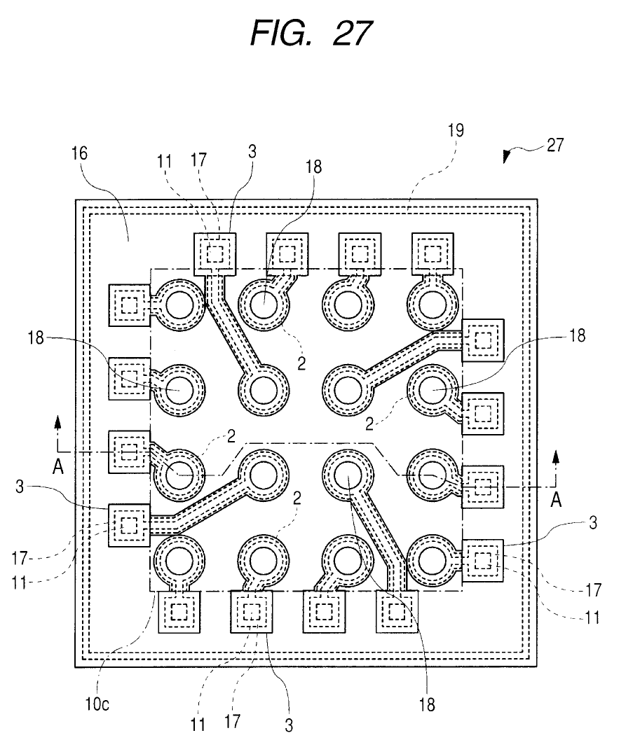

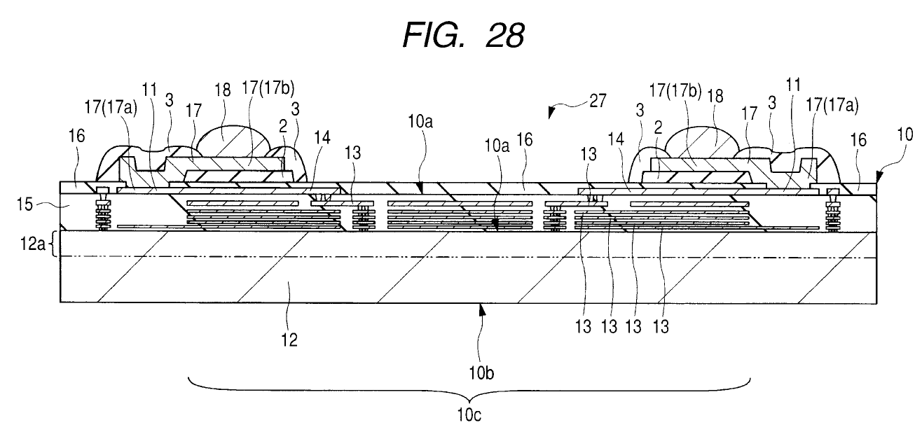

In this embodiment, a description will be given to a configuration in which by further reducing the distribution amount of the insulation film than with the WPP 1 described in Embodiment 1, the warpage occurring in the semiconductor chip 10 is further reduced. FIG. 27 is a plan view showing the overall structure of a semiconductor device which is a modified example of the semiconductor device shown in FIG. 1; and FIG. 28 is a cross-sectional view along line A-A shown in FIG. 27.

A difference between the WPP 27 of this embodiment shown in FIGS. 27 and 28, and the WPP 1 described in Embodiment 1 resides in the planar disposition of the insulation film 2. Namely, for the WPP 27, the insulation film 2 is not formed around the pads 11. The bonding part 17a of the redistribution wiring 17 is formed over the insulation layer 16 not via the insulation film 2. On the other hand, in a region in which the land part 17b of the redistribution wiring 17, namely, the external terminal is formed, the insulation film 2 is formed between the redistribution wiring 17 and the insulation layer 16.

As described in Embodiment 1, the insulation film 2 is formed from the viewpoint of reducing the noise on each circuit formed in the semiconductor chip 10, or, from the viewpoint of releasing the stress applied to the bumps 18, and preventing poor junction of the joint part of each bump 18.

In the semiconductor chip 10, various circuits are formed. However, in the main surface 10a of the semiconductor chip 10, the main circuit (core circuit) is disposed in a main circuit formation region 10c disposed at the center of the main surface 10a. In a region surrounding the periphery of the main circuit formation region 10c (a region in which a plurality of the pads 11 are disposed along the outer edge of the main surface 10a), there are formed an input/output circuit for electrically coupling the main circuit with the pads 11, and an auxiliary circuit such as a protection circuit for protecting the main circuit from static electricity. Herein, the main circuit denotes a main circuit having a function required of the semiconductor chip 10. For example, when the semiconductor chip 10 is a controller type chip, the main circuit corresponds to a control circuit. When the semiconductor chip 10 is a memory chip, the main circuit corresponds to a memory circuit or the like.

The region particularly feared to be affected by the noise caused by the formation of the redistribution wiring 17 is the main circuit formation region 10c including the main circuit formed therein. As for the auxiliary circuit, the effect is smaller than for the main circuit.

Therefore, in this embodiment, in only the main circuit formation region which is particularly feared to be affected by the noise due to the formation of a redistribution wiring, the insulation film 2 is formed. In the surrounding region including the pads 11 disposed therein, the insulation film 2 is not formed. As a result, it is possible to further reduce the distribution amount of the insulation film 2 over the main surface 10a than in Embodiment 1. Further, when a plurality of insulation films 2 are formed following the redistribution wirings 17, the area of each insulation film 2 can be further reduced than in Embodiment 1. Therefore, the WPP 27 can further prevent or inhibit the occurrence of warpage than the WPP 1.

Further, from the viewpoint of releasing the stress applied to the bumps 18, for the insulation film 2, it is essential only that each bump 18 is formed over the insulation film 2. Therefore, as a modified example of the WPP 27 of this embodiment shown in FIGS. 27 and 28, the insulation film 2 can also be formed only around each bump 18. In this case, it is possible to further reduce the distribution amount of the insulation film 2 as compared with the WPP 27. Whereas, when a plurality of the insulation films 2 patterned following the land parts 17b of the redistribution wirings 17 are formed, it is possible to further reduce the area of each insulation film 2 than in the WPP 27.

Further, also to Embodiment 3, respective modified examples described in Embodiments 1 and 2 are applicable.

### Embodiment 4

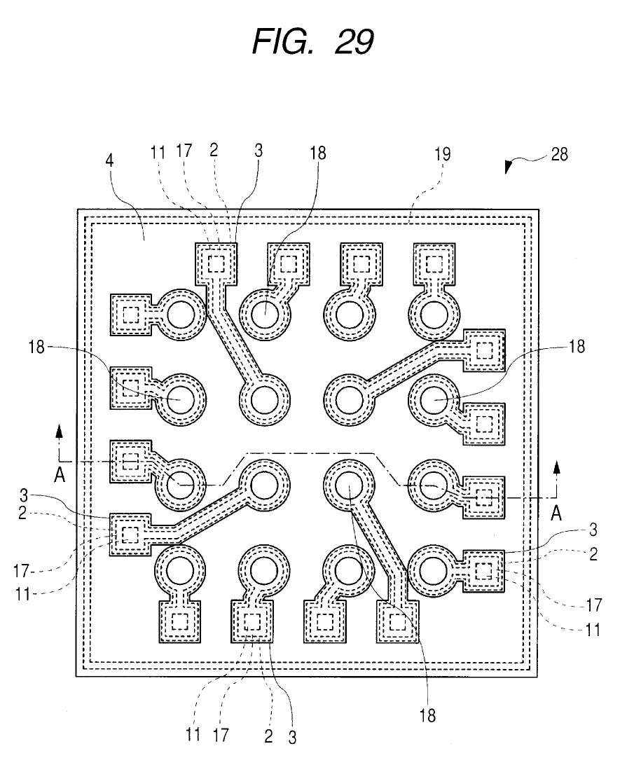

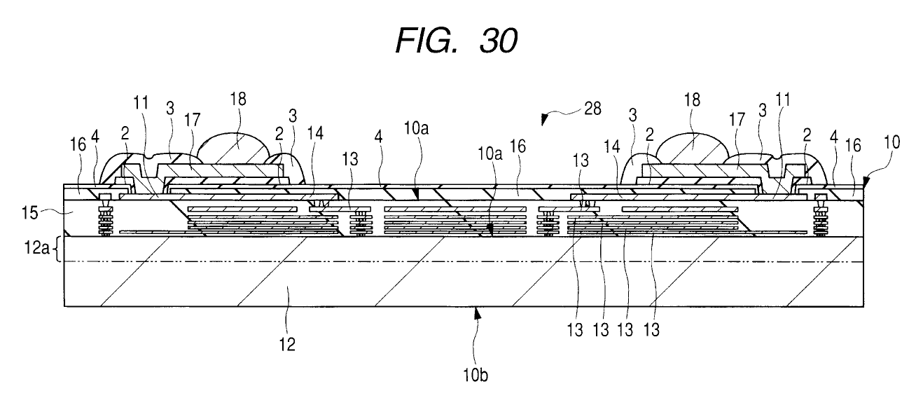

In Embodiments 1 to 3, a description was given to the examples in each of which on the main surface 10a side of the semiconductor chip 10, two layers of the organic insulation films (the insulation films 2 and 3) are formed. However, the number of layers of the organic insulation films can be set at two or more. FIG. 29 is a plan view showing the overall structure of a semiconductor device which is a second modified example of the semiconductor device shown in FIG. 19; and FIG. 30 is a cross-sectional view along line A-A shown in FIG. 29.

A difference between the WPP 28 of this embodiment shown in FIGS. 29 and 30, and the WPP 1 described in Embodiment 1 resides in the number of layers of the organic insulation films. The WPP 28 has three layers of the organic insulation films each including, for example a polyimide resin. In the WPP28, the insulation film 4 which is the third insulation film is formed, for example, between the insulation layer 16 and the insulation film 2, thereby to cover the insulation layer 16. Whereas, the insulation film 4 is formed with a smaller thickness than each thickness of the insulation films 2 and 3.

The degree of effect of the shrinkage stress occurring in the organic insulation film formed on the main surface 10a side of the semiconductor chip 10 exerted on the warpage of the semiconductor chip 10 also varies according to, other than the planar shape thereof, the thickness of the organic insulation film. In other words, by reducing the thickness of the organic insulation film, it is possible to prevent or inhibit warpage of the chip 10.

For the WPP28, by forming the insulation film 4 which is an organic insulation film covering the insulation layer 16, as described in Embodiment 2, in the case of face-down mounting, it is possible to improve the adhesion with the underfill resin.

Further, it is essential only that the insulation film 4 covers the insulation layer 16 including an inorganic insulation material from the viewpoint of improving the adhesion with the underfill resin. The insulation film 4 can be more reduced in thickness than the insulation films 2 and 3. Therefore, by forming the insulation film 4 with a smaller thickness than each thickness of the insulation films 2 and 3, it is possible to reduce the effect of the shrinkage stress occurring in the insulation film 4 exerted on the warpage of the semiconductor chip 10.

Further, the insulation film 2 is, as described in Embodiment 1, required to have a certain degree of thickness from the viewpoint of preventing the occurrence of a noise. However, when the insulation film 4 is formed in a layer underlying the insulation film 2 as with the WPP 27, the thickness of the insulation film 4 can also be counted as the required thickness from the viewpoint of a noise countermeasure. Therefore, it is possible to reduce the thickness of the insulation film 2 as compared with the WPP's 1, 25, 26, and 28.

Incidentally, the insulation film 4 is formed between the insulation layer 16 and the insulation film 2. This is for the following reason. In the step of forming the insulation film 4, the insulation film 4 can be formed thinly and finely with more stability over the insulation layer 16 high in flatness than over the insulation film 2. Further, in consideration of the adhesion with the underfill resin, the insulation film 4 is preferably formed in such a manner as to cover entirely the insulation layer 16. However, it is naturally understood that, for example, even when the insulation layer 4 is formed over a severe characteristic device region, or only at bump formation sites, the insulation layer 4 is effective.

Further, also to Embodiment 4, respective modified examples described in Embodiments 1 to 3 are applicable.

### Embodiment 5

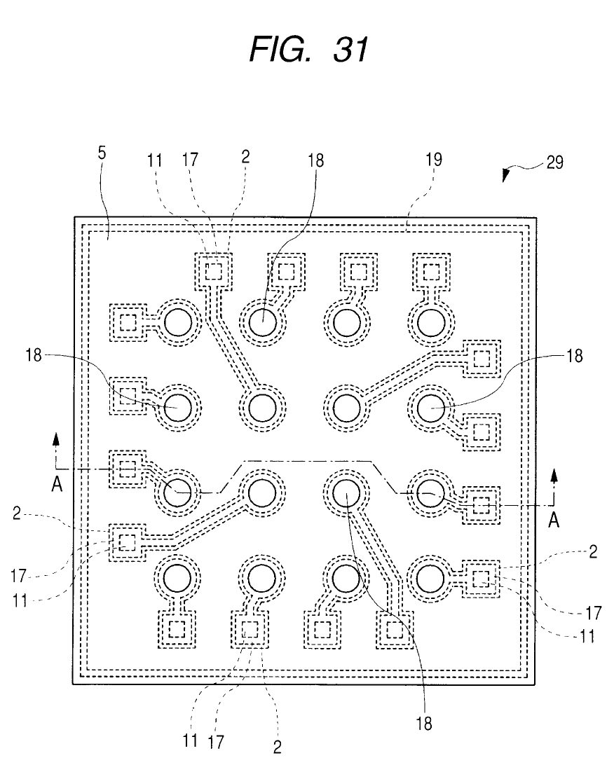

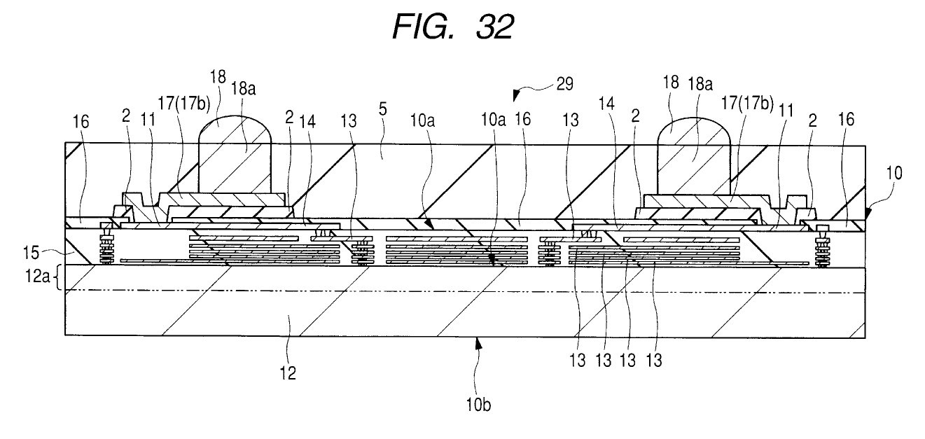

In this embodiment, as a modified example of the WPP's described in Embodiments 1 to 4, a description will be given to an embodiment in which the surface of the main surface side of the semiconductor wafer is sealed with a sealing body. FIG. 31 is a plan view showing the overall structure of the semiconductor device of this embodiment; and FIG. 32 is a cross-sectional view along line A-A shown in FIG. 31.

A difference between the WPP 29 of this embodiment and the WPP 1 described in Embodiment 1 resides in that the redistribution wiring 17 is sealed with a sealing resin (sealing body) 5. The redistribution wiring 17 and the insulation film 2 included in the WPP 29 are sealed with a sealing resin 5 including, for example, an epoxy type resin.

The sealing resin 5 is formed by, for example, a so-called batch molding process (batch transfer molding process) in which the main surface side of the wafer is sealed with a plurality of device regions joined together (with a plurality of product formation regions covered with one cavity included in a molding die). This process requires a step of heating the molding die, and pouring the molding resin therein. For this reason, in the molding step (sealing step), the warpage of the wafer is required to be inhibited. However, in this embodiment, the insulation film 2 is formed in the same manner as the insulation film 2 of the WPP 1 described in Embodiment 1. This can inhibit the warpage of the wafer.

For the WPP 29, the main surface side of the semiconductor chip 10 is covered with the integrally formed sealing resin 5. Therefore, from the viewpoint of preventing the warpage of the completed semiconductor chip 10, the WPP 1 described in Embodiment 1 is more preferable. For this reason, when sealing is carried out with the sealing resin 5 as in the WPP 29, preferably, for example, in addition to the epoxy type resin, an inorganic filler such as a silicon filler is added, thereby to make the linear expansion coefficient of the sealing resin close to each linear expansion coefficient of the semiconductor substrate 12, and the insulation layers 15 and 16 which are inorganic insulation layers.

Incidentally, in this embodiment, in order to cover the redistribution wiring 17 with the sealing resin 5, the bump 18 and the land part 17b of the redistribution wiring 17 are electrically coupled with each other via a copper post which is a conductive member formed in a column (conductive member) 18a. Further, the copper post 18a is formed, for example, over the land part 17b, and the sealing resin 5 is formed in such a manner as to seal the copper post 18a. Then, by grinding the sealing resin 5, a part of the copper post 18a sealed with the sealing resin 5 is exposed, thereby to establish an electric coupling with the bump 18.

Further, for the WPP 29, the sealing resin 5 functions as a protective layer for protecting the redistribution wiring 17, and hence the insulation film 3 described in Embodiment 1 is not formed. However, as with the WPP 1 described in Embodiment 1, it is also acceptable that the insulation film 3 covering the redistribution wiring 17 is formed. In this case, the insulation film 3 is interposed between the redistribution wiring 17 and the sealing resin 5. Accordingly, the insulation film 3 can be allowed to function as a migration inhibition layer for preventing so-called migration, penetration of metal components of the redistribution wiring 17 into the sealing resin 5.

### Embodiment 6

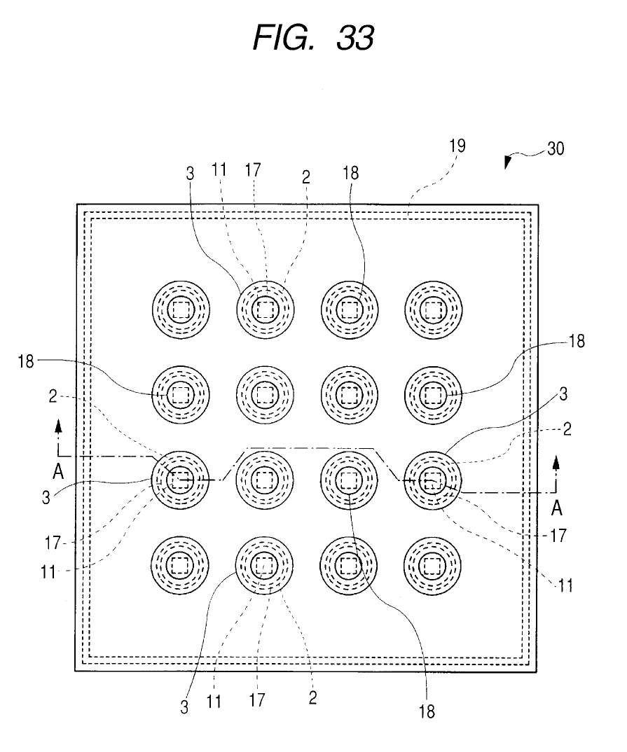

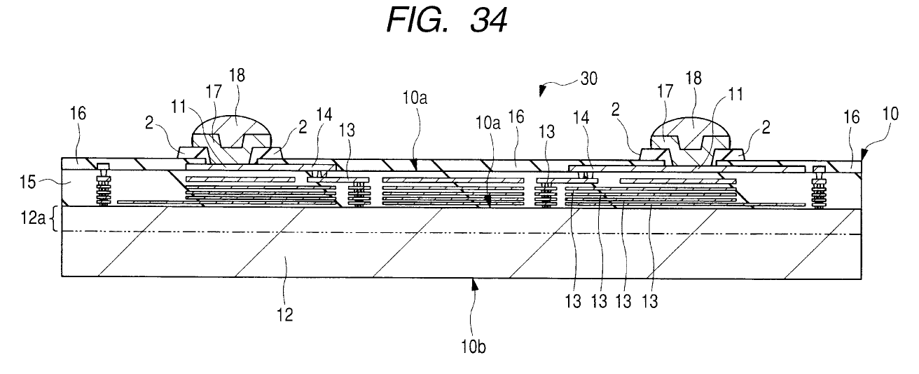

In Embodiments 1 to 5, a description was given to the configuration in which the pads 11 are disposed along the periphery of the semiconductor chip 10, and a plurality of external terminals are formed in a matrix at different positions in plan view from those of the pads 11 by the redistribution wirings 17. In this embodiment, a description will be given to the following embodiment: on the main surface 10a of the semiconductor chip 10, a plurality of the pads 11 are disposed in a matrix, and over a plurality of the pads 11, external terminals are respectively formed. FIG. 33 is a plan view showing the overall structure of the semiconductor device of this embodiment; and FIG. 34 is a cross-sectional view along line A-A shown in FIG. 33.

A difference between the WPP 30 of this embodiment and the WPP 1 described in Embodiment 1 resides in that on the main surface of the semiconductor chip 10, a plurality of the pads 11 are disposed in a matrix, and the bumps 18 which are external terminals are formed at the same planar positions of the pads 11 (positions at which the pads 11 and the bumps 18 overlap each other in plan view, respectively), respectively.

For the WPP 30 of this embodiment, over the pad 11, the insulation film 2, the redistribution wiring 17, and the bump 18 are successively stacked. In other words, the bump 18 is formed over the insulation film 2 with a lower elasticity (than that of an inorganic insulation layer) such as a polyimide resin. For this reason, even when a stress is applied to the bump 18 after mounting of the WPP 30, the stress can be released by the insulation film 2. This can inhibit a defect such as peeling at the joint part between the bump 18 and the redistribution wiring 17, or at the joint part between the redistribution wiring 17 and the pad 11.

Further, the bump 18 and the pad 11 are electrically coupled with each other at a portion on the peripheral side thereof via the redistribution wiring 17 disposed over the insulation film 2. This results in that a portion of the peripheral side of the bump 18 is disposed at a position overlying the insulation film 2. As a result, the stress applied to the bump 18 can be released by the insulation film 2. Thus, the metal layer formed between the bump 18 and the pad 11 is referred to as a so-called under bump metal (UBM), and includes a metal material (conductive member) such as copper or a lamination body of copper and nickel.

Thus, also in the WPP 30, the insulation film 2 is formed. Therefore, as with the insulation film 2 described in Embodiment 1, the insulation film 2 is patterned, which can prevent or inhibit the warpage of the WPP 30. Further, a parasitic capacitance can be caused between the insulation film 2 and the main circuit arranged on the lower side of the insulation film 2. This can inhibit the degradation of the characteristics of the semiconductor device.

Incidentally, for the WPP 30, the bump 18 covers the entire top surface of the redistribution wiring 17, and the insulation film 3 described in Embodiment 1 is not formed. Such a bump 18 can be also formed by, other than the formation method in which solder balls are disposed described Embodiment 1, an electrolytic plating process. The method of formation by the electrolytic plating process will be briefly described. A seed layer to be electrically coupled with the redistribution wiring 17 is formed. Then, a resist film is formed in such a manner as to expose a region in which solder is plated and formed. Then, a current is allowed to flow through the seed layer, so that solder is formed by electrolytic plating. Then, the resist film and unnecessary portions of the seed layer are removed. This results in the formation of a plated and formed solder layer (plated solder layer) following the redistribution wiring 17. Then, when the plated solder layer is heated, the plated solder layer is deformed by the surface tension of solder. Thus, as shown in FIG. 34, ball-shaped bumps 18 can be formed. Incidentally, in this embodiment, the formation method by an electrolytic plating process was described. However, an electroless plating process may be used.

However, as a modified example of this embodiment, in a layer overlying the insulation film 2, there can also be formed an insulation film covering the side surface of the redistribution wiring 17 (organic insulation film corresponding to the insulation film 3 shown in FIG. 2). An overlying detailed description thereon will be omitted. However, to this case, the technology described in Embodiments 1 to 4 can be used and applied. Further, as described in Embodiment 5, there can also be employed an embodiment in which the main surface 10a side of the semiconductor chip 10 is sealed with a sealing resin.

### Embodiment 7

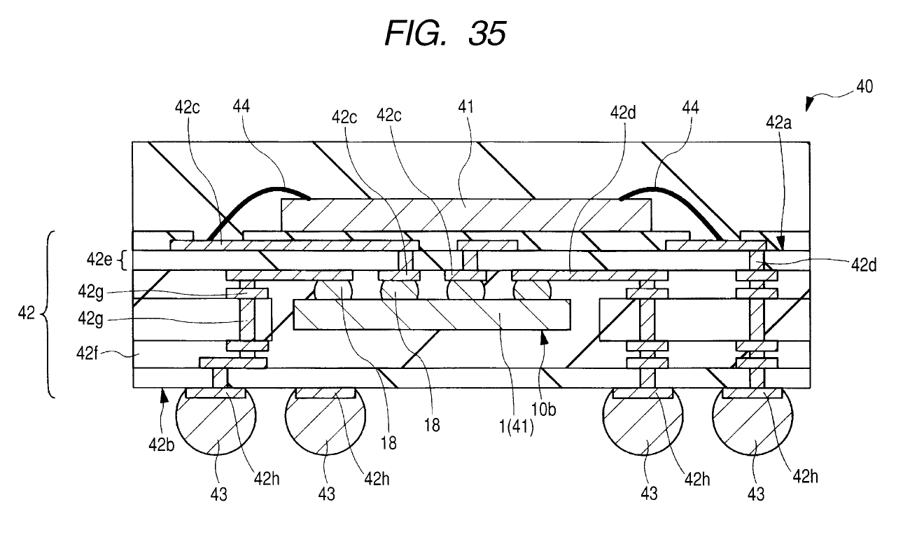

In this embodiment, a description will be given to one embodiment of the embodiments of the WPP's described in Embodiments 1 to 6. FIG. 35 is a cross-sectional view showing the overall structure of a semiconductor device of this embodiment.

A semiconductor device 40 shown in FIG. 35 has a plurality of electronic components 41 including the WPP 1 described in Embodiment 1, and a wiring substrate 42 including the electronic components 41 mounted thereon. The wiring substrate 42 has a surface (main surface) 42a and a back surface 42b arranged on the opposite side of the surface 42a. The surface 42a includes the electronic components 41 mounted thereon. The back surface 42b includes the bumps 43 which are external terminals of the semiconductor device 40 formed thereon. Incidentally, in this embodiment, the electronic components 41 mounted on the surface 42a are also semiconductor chips, and are electrically coupled with bonding leads 42c formed on the surface 42a of the wiring substrate 42 via wires 44.

Herein, the WPP 1 is embedded and mounted inside the wiring substrate 42. In other words, the wiring substrate 42 includes therein the WPP 1. The WPP 1 is included in the wiring substrate 42, and is electrically coupled with other electronic components 41 mounted in the wiring substrate 42 via the bumps 18 which are external terminals, or, with the bumps 43 which are external terminals of the semiconductor device 40. Thus, by embedding and mounting the WPP 1 in the wiring substrate 42, the planar dimensions of the semiconductor device 40 can be reduced.

Herein, when the electronic component 41 is embedded and mounted in the wiring substrate 42, the thickness of the wiring substrate 42 becomes too large according to the thickness of the electronic component 41. Accordingly, the semiconductor device 40 may be unable to be sufficiently reduced in thickness. Thus, in this embodiment, the WPP 1 reduced in thickness with the back surface 10b ground is embedded and mounted inside the wiring substrate 42. This can inhibit the increase in thickness of the semiconductor device 40.

Incidentally, in this embodiment, a description will be given by taking the WPP 1 described in Embodiment 1 as an mounting example of a thin type WPP. However, the WPP's described in Embodiments 2 to 4, or Embodiment 6 can also be reduced in thickness, and hence are applicable. Whereas, the WPP 29 described in Embodiment 5 is thicker than other WPP's in that the sealing resin 5 is formed on the main surface 10a side of the semiconductor chip 10. However, the WPP 29 can be reduced in thickness to a certain degree by grinding of the back surface 10b.

The step of embedding and mounting the WPP 1 in the wiring substrate 42 can be carried out, for example, in the following manner. First, there is prepared a substrate 42e thinner than the wiring substrate 42, and including a plurality of bonding leads 42c respectively formed on the front surface and the back surface thereof, which are electrically coupled with each other via wirings 42d including surface wirings, back surface wirings, and interlayer conductive paths such as through holes. Then, by mounting the WPP 1 on the back surface side of the substrate 42e, a plurality of the bumps 18 of the WPP 1 and the bonding leads 42c on the back surface side are electrically coupled with each other, respectively. Herein, when a large warpage occurs in the WPP 1, bonding between the bumps 18 and the bonding leads 42c becomes difficult. However, as described in the foregoing embodiments, the WPP 1 can inhibit the warpage, and hence can be mounted with ease. Then, on the back surface side of the substrate 42e including the WPP 1 mounted thereon, an insulation material 42f including, for example, a base material containing glass fiber (e.g., prepreg), or an epoxy type rein is disposed. Thus, the WPP 1 is sealed in such a manner as to be embedded in the insulation material 42f. Further, the wirings 42g in the substrate to be electrically coupled with the bonding leads 42c of the substrate 42e, and lands 42h to be electrically coupled with the wirings 42g, and for forming the bumps 43 are successively formed, resulting in the wiring substrate 42.

Incidentally, the foregoing description relates to one example of the step of embedding and mounting the WPP 1 in the wiring substrate 42, to which other various modified examples are applicable. For example, the following process may be adopted: as the wiring substrate 42 shown in FIG. 35, there is prepared the wiring substrate 42 including a cavity formed in a region in which the WPP 1 is to be disposed. Then, the WPP 1 is disposed in the cavity, and then the inside of the cavity is filled with the insulation material 42f. In this case, the coupling between the WPP 1 and the bonding leads 42c can be formed with ease by embedding a conductive member such as copper in each through hole penetrating from the surface of the insulation material 42f through the land part 17b of the WPP 1 (see FIG. 4) as with the copper posts 18a (see FIG. 32) described in Embodiment 5 in place of the bumps 18. Thus, when the WPP 1 is disposed in the cavity, and is sealed with the insulation material 42f, and then, the copper posts 18a are formed, it becomes important from the viewpoint of the coupling reliability to form the through hole for forming each copper post 18a with good alignment precision. Therefore, the alignment precision for disposing the WPP 1 in the cavity becomes important. From this viewpoint, the WPP 1 can inhibit the occurrence of warpage. This can improve the alignment precision for disposition in the cavity.

### Embodiment 8

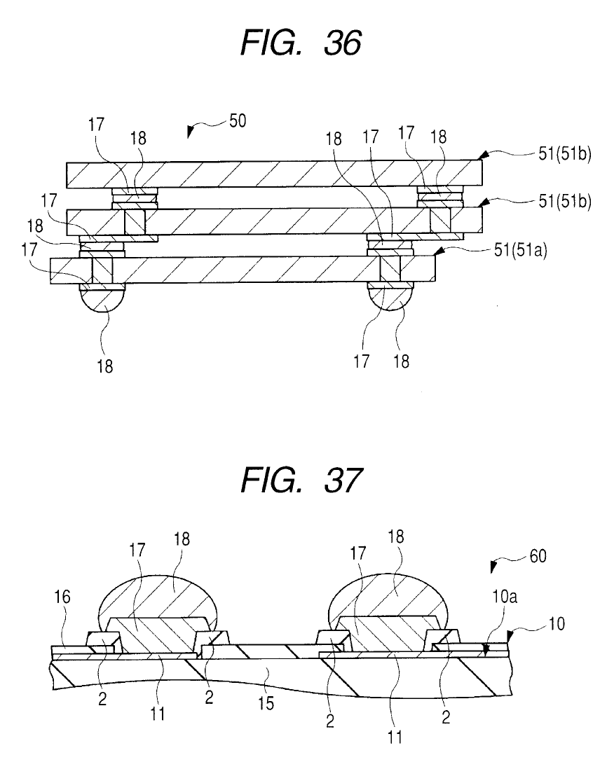

In this embodiment, a description will be given to a mounting form of stacking of a plurality of semiconductor devices. FIG. 36 is a cross-sectional view showing the overall structure of a semiconductor device of this embodiment. A semiconductor device 50 shown in FIG. 36 is a multilayer semiconductor device including a plurality of the WPP's 51 stacked therein. Respective WPP's 51 are electrically coupled to one another via the redistribution wirings 17 and the bumps 18 respectively formed on respective main surface sides of the semiconductor chips respectively included therein. In this embodiment, for example, the WPP 51a disposed at the lowermost stage is a WPP having a microcomputer chip including an operation circuit formed therein. A plurality of the WPP's 51b mounted on the upper stages than that of the WPP 51a are WPP's each having a memory chip including a memory circuit formed therein. The WPP's 51a and 51b are electrically coupled with each other via through electrodes formed with a through silicon via (TSV) technology in the intermediate-stage (second-stage) WPP 51b, thereby to form a system. This results in a multi-chip module. In other words, the intermediate-stage WPP 51b is a memory chip, and in addition, also has a function as an interposer chip.

The multilayer semiconductor device including a plurality of semiconductor chips thus mounted in a stacked form therein is preferable from the viewpoint of reducing the mounting area of the semiconductor chips. However, in order to stack a plurality of semiconductor chips different in planar positions of the external terminals on the main surface, and electrically coupling these, for example, as with the WPP 51b at the second stage from the top stage shown in FIG. 36, there is caused a necessity of changing the positions of the external terminals for alignment. Under such circumstances, in this embodiment, there is stacked the WPP capable of being changed in planar positions of the external terminals on the main surface of the semiconductor chip. Further, the WPP can be reduced in thickness by being ground on the back surface 10b as described in the foregoing embodiments. Therefore, the WPP is preferable in terms of being capable of inhibiting the increase in thickness of the multilayer semiconductor device. For example, when the semiconductor device 50 shown in FIG. 36 can be reduced in thickness, the semiconductor device 50 can also be embedded and mounted inside the wiring substrate 42 in place of the WPP 1 shown in FIG. 35 described in Embodiment 7.

For such a multilayer semiconductor device, when warpage occurs in each WPP 51, a stress is concentrated to the junction part of each bump 18 which is an external terminal. This may cause poor electric coupling. Under such circumstances, by applying the technologies described in Embodiments 1 to 7, the warpage of each WPP 51 can be prevented or inhibited. Therefore, poor electric coupling can be prevented for improving the reliability of the semiconductor device 50.

Up to this point, the invention made by the present inventors was specifically described by way of embodiments. However, the present invention is not limited to the foregoing embodiments, and it is naturally understood that various modifications may be made within the scope not departing from the gist thereof.

For example, in Embodiments 1 to 8, a description was given to the formation process by electrolytic plating as the formation process of the redistribution wiring 17. However, other formation processes are also applicable thereto. FIG. 37 is an essential part enlarged cross-sectional view showing a modified example of the redistribution wirings shown in FIG. 34. For the WPP 60 shown in FIG. 37, the redistribution wirings (under bump metals) 17 are formed by an electroless plating process. With the electroless plating process, each redistribution wiring 17 is formed by the chemical reaction between the plating material and the metal. Therefore, the redistribution wiring 17 is grown from the exposed surface of each pad 11, to be formed. Therefore, as described in Embodiment 6, this process is applicable to the case where each bump 18 is formed at a position overlying, in plan view, the pad 11. In this case, as compared with the electrolytic plating process, it is possible to omit the steps of forming and removing the seed layer and the resist layer. This can simplify the manufacturing step.

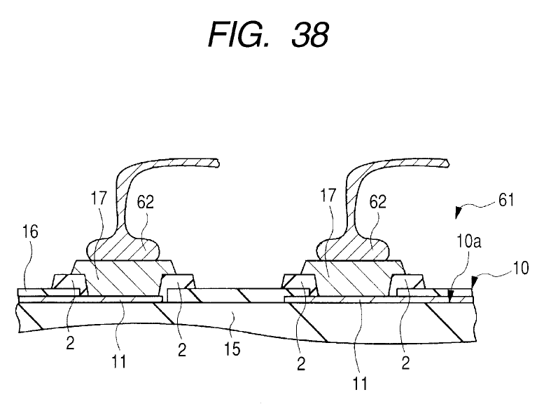

Further, for example, in Embodiments 1 to 8, a description was mainly given to the embodiments in which the WPP and the external devices are electrically coupled with each other via the bumps 18. However, coupling can also be established by other conductive members. FIG. 38 is an essential part enlarged cross-sectional view showing a modified example of the bumps shown in FIG. 37. For the WPP 61 shown in FIG. 38, each redistribution wiring 17 is bonded to one end of the wire 62 including a conductive member. Although not shown, the other end of the wire 62 is bonded to an external device, so that the WPP 61 is electrically coupled thereto via the wire 62. When the redistribution wiring 17 is thus bonded with the wire 62, for example, in the semiconductor device 40 described in Embodiment 7, the electronic component 41 mounted on the surface 42a can be replaced with the WPP 61. As a result, for example, even when a wire including copper (Cu) is used for a semiconductor chip having pads including gold (Au) or palladium (Pd) other than aluminum (Al), wire bonding is possible because the redistribution wirings 17 are formed on the pads 11.

Further, for example, in Embodiment 1, a description was given to use of the bump 18 including a solder material as a conductive member. However, in consideration of the contents of the foregoing description, formation of the under bump metal on each pad 11 also enables bonding of the bump 18 including, for example, copper (Cu). Further, formation of the under bump metal enables absorption of development of a stress to the pad upon bonding of the bump including a relatively hard material on the pad.

Further, for example, in Embodiments 1 to 8, a description was given to use of the semiconductor wafer (or the semiconductor chip) with no insulation layer nor insulation film formed on the back surface side. However, any semiconductor wafer with an insulation layer or an insulation film formed on the back surface side is acceptable so long as the insulation layer or the insulation film has a smaller thickness than the total thickness of the insulation layer and the insulation film formed on the main surface side of the semiconductor wafer. Even in the case of such a semiconductor wafer, the difference in total thickness between the insulation layers or the insulation films formed on the main surface and the back surface of the semiconductor chip, respectively, also causes a difference in thermal expansion coefficient. As a result, warpage occurs in the semiconductor wafer. Then, when the total thickness of the insulation layer and the insulation film formed on the main surface side is larger than the total thickness of the insulation layer and the insulation film formed on the back surface side, as in Embodiments 1 to 8, a part of any one of the insulation layer or the insulation film formed on the main surface side is removed. This can inhibit the warpage.

Further, for example, in Embodiments 1 to 8, a description was given to the procedure in which, before the formation of the bumps 18, the insulation film 2 or the insulation film 3 is patterned. However, the following procedure is also acceptable: after the formation of the bumps 18, the insulation film 2 or the insulation film 3 is patterned; and then, the back surface 10b of the semiconductor wafer 20 is ground. In this case, for example, the bumps 18 are absorbed by a protective tape or the like, and then, the back surface 10b of the semiconductor wafer 20 is ground. However, as described above, when the bumps 18 are formed, the semiconductor wafer 20 is heated. Therefore, not only warpage tends to occur in the semiconductor wafer 20, but also a member for absorbing the bumps 18 such as a protective tape becomes necessary. Further, it is difficult to grind the semiconductor wafer while absorbing the bumps. For these reasons, as described above, it is preferable that, before the formation of the bumps 18, the insulation film 2 or 3 is patterned.

The present invention is particularly applicable to a WPP including wirings further formed over the pads-formed main surface of the semiconductor chip.

What is claimed is:

1. A method for manufacturing a semiconductor device, comprising the steps of:
(a) providing a semiconductor wafer having a main surface, a plurality of device regions formed over the main surface, a plurality of first electrodes formed in each of the device regions, a scribe region formed between the device regions of the device regions adjacent to each other, and a back surface positioned on the opposite side of the main surface;
(b) grinding the back surface of the semiconductor wafer;
(c) disposing a plurality of conductive members to be electrically coupled with the first electrodes on the main surface side, respectively; and
(d) dividing the semiconductor wafer along the scribe region, and obtaining a plurality of semiconductor chips,
wherein the main surface includes a semiconductor element layer including a plurality of semiconductor elements formed therein, and a plurality of first wirings stacked over the semiconductor element layer via a plurality of first insulation layers, and electrically coupled with the semiconductor elements,
wherein the first electrodes, a second wiring for electrically coupling the first electrodes and the semiconductor elements, and a second insulation layer formed by covering the first wirings, the second wirings and the first insulation layer such that the first electrodes are exposed are formed over the main surface,
wherein the step (a) includes the steps of:
(a1) forming a first insulation film over the second insulation layer such that the first electrodes are exposed;
(a2) forming a plurality of third wirings to be electrically coupled with the first electrodes, respectively, over the first insulation film; and
(a3) forming a second insulation film over the third wirings such that portions of the third wirings are exposed,
wherein the conductive members are bonded to the regions of the third wirings exposed from the second insulation film, respectively, and
wherein any one of the first insulation film and the second insulation film is formed such that a portion of an insulation layer or the first insulation film formed closer to the back surface side than the first insulation film or the second insulation film is exposed.

2. The method for manufacturing a semiconductor device according to claim 1, wherein any one of the first insulation film and the second insulation film is formed following the planar shape of the third wiring.

3. The method for manufacturing a semiconductor device according to claim 2, wherein the first insulation layers include an inorganic insulation material, and the first insulation film includes an organic insulation material lower in dielectric constant than the inorganic insulation material.

4. The method for manufacturing a semiconductor device according to claim 3, wherein the first and second insulation films each include an organic insulation material lower in elasticity than the first insulation layers.

5. The method for manufacturing a semiconductor device according to claim 4, wherein the first insulation film is formed following the planar shape of the first wiring.

6. The method for manufacturing a semiconductor device according to claim 5,
wherein the second insulation film is formed following the planar shape of the first wiring, and
wherein the side surface of the first insulation film is covered with the second insulation film.

7. The method for manufacturing a semiconductor device according to claim 2,
wherein a region for disposing therein the third wirings includes a first region for disposing therein the adjacent third wirings at a first distance, and a second region for disposing therein the third wirings at a second distance larger than the first distance,
wherein in the first region, the first insulation film or/and the second insulation film are respectively independently formed for each of the third wirings, and
wherein in the second region, one integrated insulation film is formed for a plurality of the adjacent redistribution wirings.

8. The method for manufacturing a semiconductor device according to claim 2,
wherein the adjacently disposed third wirings have a first region in which these are respectively disposed at a first distance, and a second region in which these are disposed at a second distance larger than the first distance,
wherein in the first region, the first insulation films or/and the second insulation films are respectively integrally formed, and
wherein in the second region, the first insulation films or/and the second insulation films are respectively formed apart from each other.

9. The method for manufacturing a semiconductor device according to claim 2, wherein any one of the first insulation film and the second insulation film is formed along the outline of the third wiring.

10. The method for manufacturing a semiconductor device according to claim 2, wherein the third wiring is in a lamination structure of a copper film including copper and a metal film including a metal material smaller in linear expansion coefficient than copper.

11. The method for manufacturing a semiconductor device according to claim 2, further comprising a step of embedding and mounting the semiconductor chip obtained in the step (d) in a wiring substrate.

12. The method for manufacturing a semiconductor device according to claim 2,
wherein the conductive members disposed in the step (c) are bump electrodes each to be electrically coupled with a portion of each of the third wirings,
the method further comprising a step of preparing a wiring substrate including a plurality of bonding leads formed on a chip mounting side thereof, and bonding the bonding leads and the bump electrodes, respectively, and then, filling the gap between the chip mounting side and the main surface of the semiconductor chip with an underfill resin.

13. The method for manufacturing a semiconductor device according to claim 2,
wherein the conductive members disposed in the step (c) are wires each to be electrically coupled with a portion of each of the third wirings,
the method further comprising a step of sealing the wires with a sealing resin.

14. A method for manufacturing a semiconductor device, comprising the steps of:
(a) providing a semiconductor wafer having a main surface, a plurality of device regions formed over the main surface, a plurality of first electrodes formed in each of the device regions, ascribe region formed between the device regions of the device regions adjacent to each other, and a back surface positioned on the opposite side of the main surface;
(b) grinding the back surface of the semiconductor wafer;
(c) disposing a plurality of conductive members to be respectively electrically coupled with the first electrodes on the main surface side, respectively; and
(d) dividing the semiconductor wafer along the scribe region, and obtaining a plurality of semiconductor chips,
wherein the main surface includes a semiconductor element layer including a plurality of semiconductor elements formed therein, and a plurality of first wirings stacked over the semiconductor element layer via a plurality of first insulation layers, and electrically coupled with the semiconductor elements,
wherein the first electrodes, a second wiring for electrically coupling the first electrodes and the semiconductor elements, and a second insulation layer formed by covering the first wirings, the second wirings and the first insulation layer such that the first electrodes are exposed are formed over the main surface,
wherein the step (a) includes the steps of:
(a1) forming a first insulation film over the second insulation layer such that the first electrodes are exposed; and
(a2) forming a plurality of third wirings to be electrically coupled with the first electrodes, respectively, over the first insulation film,
wherein the conductive members are each bonded to a portion of each of the third wirings, and
wherein the first insulation film is formed such that a portion of the insulation layer or the first insulation film formed closer to the back surface side than the first insulation film is exposed.

15. A semiconductor device, comprising:
a semiconductor chip having a main surface, a plurality of first electrodes formed over the main surface, and a back surface arranged on the opposite side of the main surface,
wherein the main surface includes a semiconductor element layer including a plurality of semiconductor elements formed therein, and a plurality of first wirings stacked over the semiconductor element layer via a plurality of first insulation layers, and electrically coupled with the semiconductor elements,
wherein, the first electrodes, a second wiring for electrically coupling the first electrodes and the semiconductor elements, a second insulation layer formed by covering the first wirings, the second wirings and the first insulation layer such that the first electrodes are exposed, a first insulation film formed over the second insulation layer such that the first electrodes are exposed, a plurality of third wirings electrically coupled with the first electrodes, respectively, over the first insulation film, a second insulation film formed over the third wirings such that a portion of each of the third wirings is exposed, and a plurality of conductive members respectively bonded to the regions of the third wirings exposed through the second insulation film, are formed over the main surface, and
wherein any of the first insulation film and the second insulation film is formed such that a portion of the insulation layer or the first insulation film formed closer to the back surface side than the first insulation film or the second insulation film is exposed.

16. The semiconductor device according to claim 15,
wherein a region for disposing therein the third wirings includes a first region for disposing therein the adjacent third wirings at a first distance, and a second region for disposing therein the third wirings at a second distance larger than the first distance,
wherein in the first region, the first insulation film or/and the second insulation film are respectively independently formed for each of the third wirings, and
wherein in the second region, one integrated insulation film is formed for a plurality of the adjacent redistribution wirings.

17. The semiconductor device according to claim 15,
wherein the adjacently disposed third wirings have a first region in which these are respectively disposed at a first distance, and a second region in which these are disposed at a second distance larger than the first distance,
wherein in the first region, the first insulation films or/and the second insulation films are respectively integrally formed, and
wherein in the second region, the first insulation films or/and the second insulation films are respectively formed apart from each other.

18. The semiconductor device according to claim 15, wherein any one of the first insulation film and the second insulation film is formed along the outline of the third wiring.

19. A semiconductor device, comprising:
a semiconductor chip having a main surface, a plurality of first electrodes formed over the main surface, and a back surface arranged on the opposite side of the main surface,
wherein the main surface includes a semiconductor element layer including a plurality of semiconductor elements formed therein, and a plurality of first wirings stacked over the semiconductor element layer via a plurality of first insulation layers, and electrically coupled with the semiconductor elements,
wherein the first electrodes, a second wiring for electrically coupling the first electrodes and the semiconductor elements, a second insulation layer formed by covering the first wirings, second wirings and the first insulation layer such that the first electrodes are exposed, a first insulation film formed over the second insulation layer such that the first electrodes are exposed, a plurality of third wirings electrically coupled with the first electrodes, respectively, over the first insulation film, and a plurality of conductive members respectively bonded to the third wirings, are formed over the main surface, and
wherein the first insulation film is formed such that a portion of the insulation layer or the first insulation film formed closer to the back surface side than the first insulation film is exposed.
